(19) United States
(12) Patent Application Publication
(10) Pub. No.: US 2025/0006558 A1
(43) Pub. Date: Jan. 2, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Yu-Lung TUNG, Kaohsiung City (TW); Xiaodong Wang, Hsinchu City (TW); Jhon Jhy Liaw, Hsinchu County (TW)

(73) Assignee: Taiwan Semiconductor Manufacturing Company, Ltd., Hsinchu (TW)

(21) Appl. No.: 18/344,300

(22) Filed: Jun. 29, 2023

(51) Int. Cl. H01L 21/8234; H01L 27/088; H01L 29/06; H01L 29/423; H01L 29/66; H01L 29/775; H01L 29/786

(52) U.S. Cl. CPC H01L 21/823481; H01L 21/823418; H01L 21/823437; H01L 27/088; H01L 29/0649; H01L 29/0673; H01L 29/42392; H01L 29/66439; H01L 29/66545; H01L 29/775; H01L 29/78696

(57) ABSTRACT

A method includes forming first, second, third, fourth, fifth, and sixth channel patterns on a semiconductor substrate; forming a first isolation wall interposing the first and second channel patterns, a second isolation wall interposing the third and fourth channel patterns, wherein the first isolation wall further continuously extends to interpose the fifth and sixth channel patterns; forming a first gate pattern extending across the first, second, third, and fourth channel patterns and the first and second isolation walls, and a second gate pattern extending across the fifth and sixth channel patterns and the first isolation wall from the top view, wherein the first, second, third, fourth, and sixth channel patterns respectively have first, second, third, fourth, and sixth dimensions in a lengthwise direction of the first gate pattern, and the sixth dimension is greater than the first, second, third, and fourth dimensions.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a cell array of an integrated circuit structure (or semiconductor device) in accordance with some embodiments of the present disclosure.

FIG. 1B is a layout diagram of an integrated circuit structure (or semiconductor device) in accordance with some embodiments of the present disclosure.

FIGS. 2-21D illustrate perspective views and cross-sectional views of intermediate stages in the formation of the integrated circuit structure (or the semiconductor device) in accordance with some embodiments of the present disclosure.

FIGS. 22A, 23A, 24A, 25A, and 26A are top views of cell arrays of integrated circuit structures (or semiconductor devices) in accordance with some embodiments of the present disclosure.

FIGS. 22B, 23B, 24B, and 25B, and 26B are layout diagrams of integrated circuit structures (or semiconductor devices) in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

As the demand for area scaling persists, gate-all-around (GAA) devices have been proposed to maintain the trend of increasing semiconductor density while simultaneously reducing power consumption and enhancing device speed. Among the various GAA device options, a structure known as the “Fork-Sheet” (FS) device has emerged. This design features an isolation wall between two active devices, which is narrower than conventional device-to-device isolation spaces. The isolation wall in the FS device directly abuts both devices, minimizing the isolation space required in traditional standard cells (STD). However, the maximum device size in an FS standard cell is constrained by the given cell height and the minimum device isolation space, and to achieve higher speed, wider devices is hard be accommodated within the same compact standard cell height.

Therefore, the present disclosure in various embodiments provides a method for partially removing the “isolation-wall” structure in standard cells (STD) to create a wider Fork-Sheet (FS) device across multiple cell heights of the original STD unit. Moreover, the width of the wider FS device can be adjusted by altering the position of the “isolation-wall” within the unit cell. Consequently, this disclosure presents a method to merge N-type (or P-type) FS device regions within a standard cell to form an expanded device region. It replaces the isolation wall with a minimum isolation space between the adjacent two wider FS devices, allowing the width of FS device to increase to more than 1.5 times the original FS device.

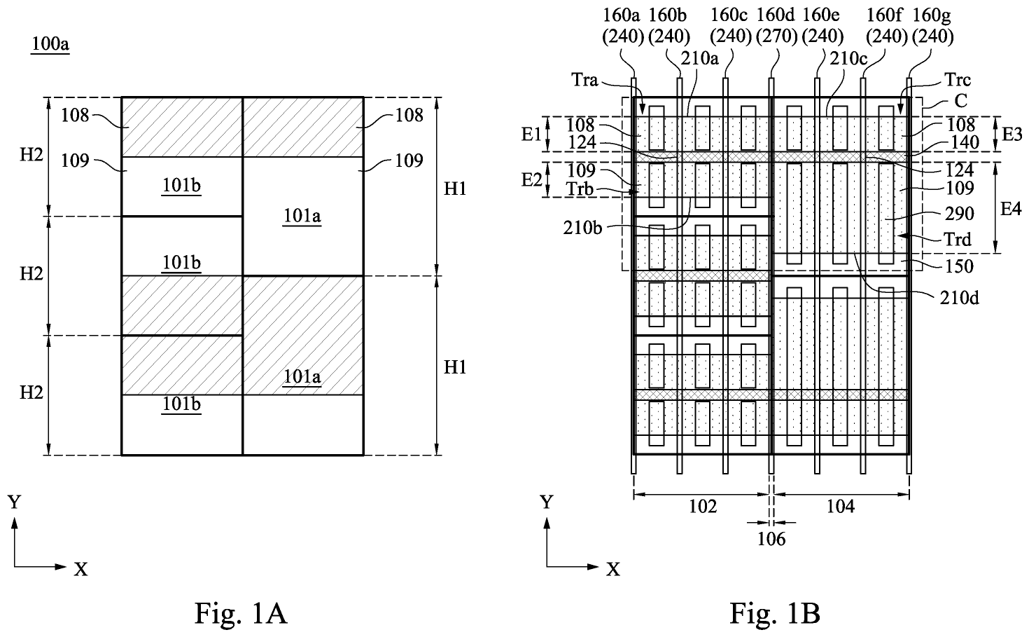

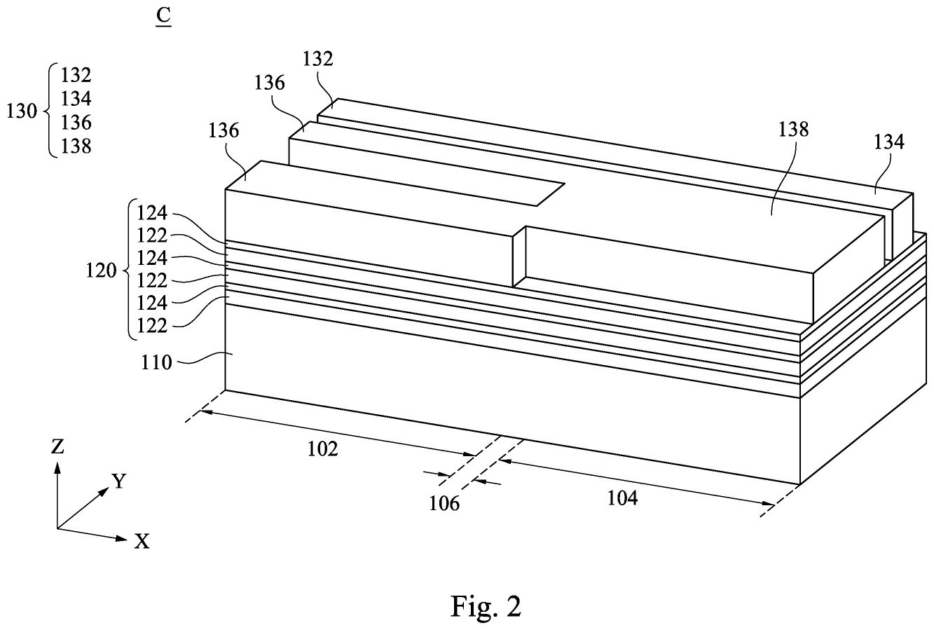

Reference is made to FIGS. 1A-21D. FIG. 1A is a top view of a cell array of an integrated circuit structure (or semiconductor device) 100a in accordance with some embodiments of the present disclosure. FIG. 1B is a layout diagram of the integrated circuit structure (or semiconductor device) 100a in accordance with some embodiments of the present disclosure. FIGS. 2-21D illustrate perspective views and cross-sectional views of intermediate stages in the formation of the integrated circuit structure (or the semiconductor device) 100a in accordance with some embodiments of the present disclosure.

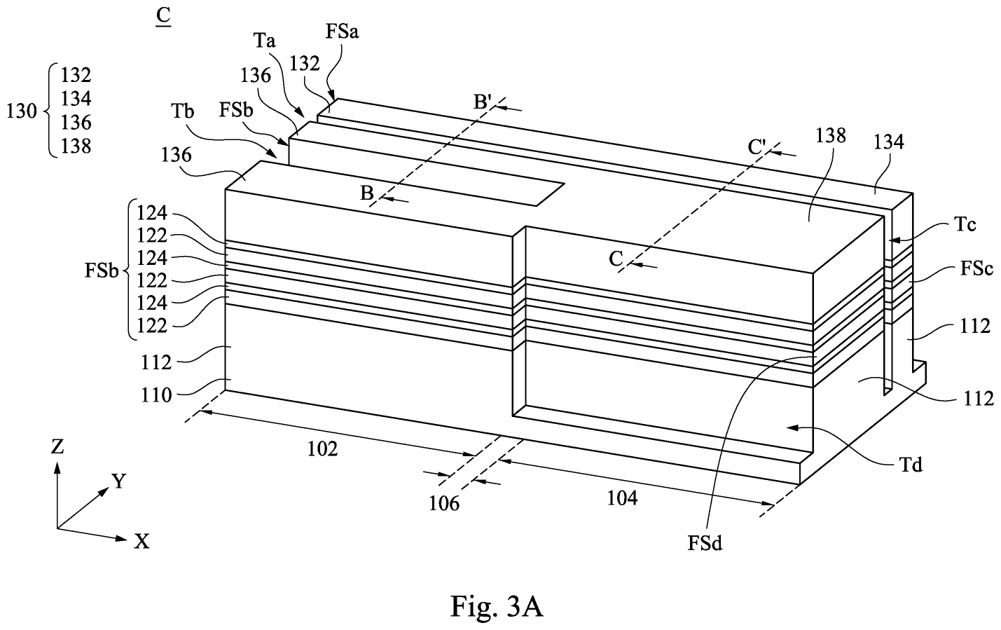

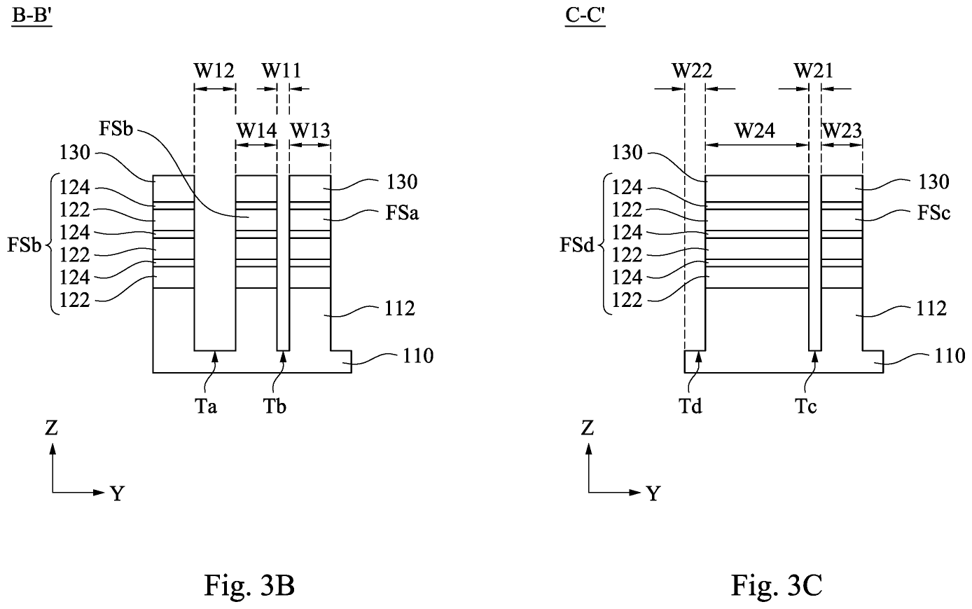

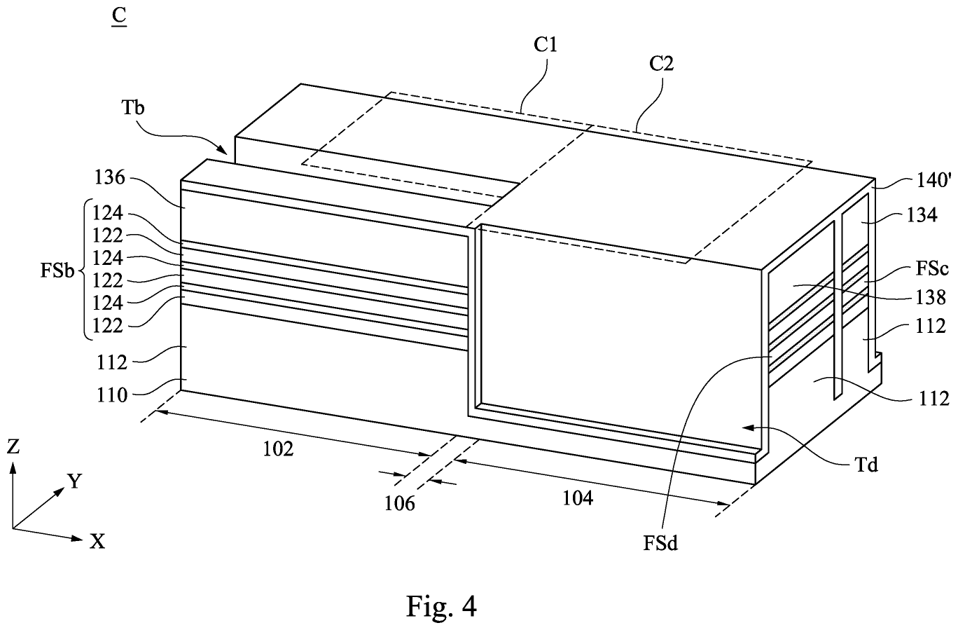

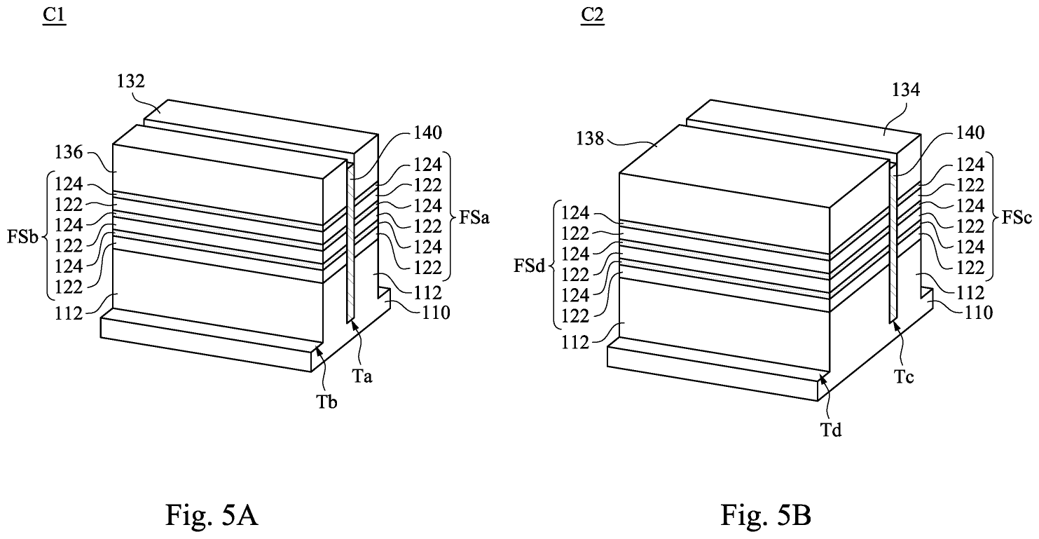

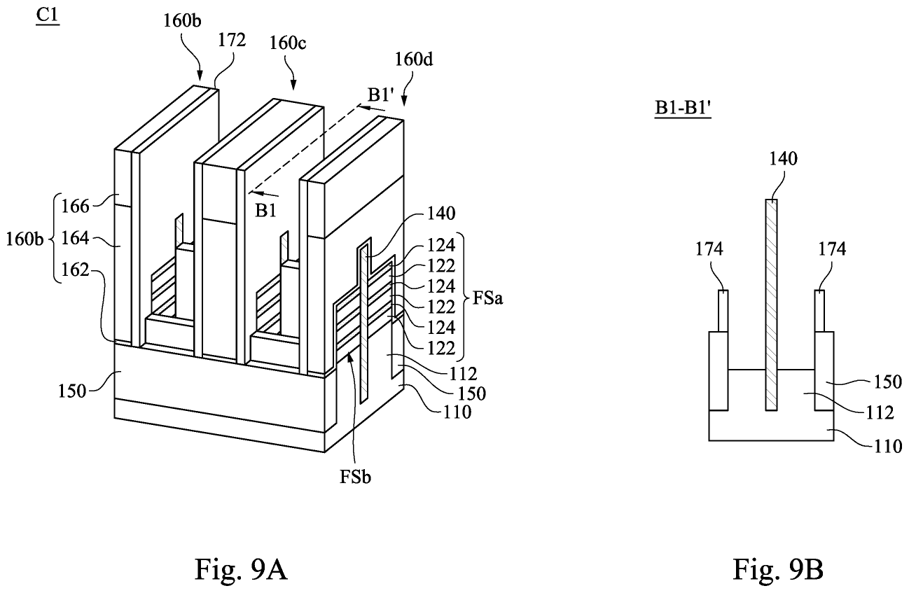

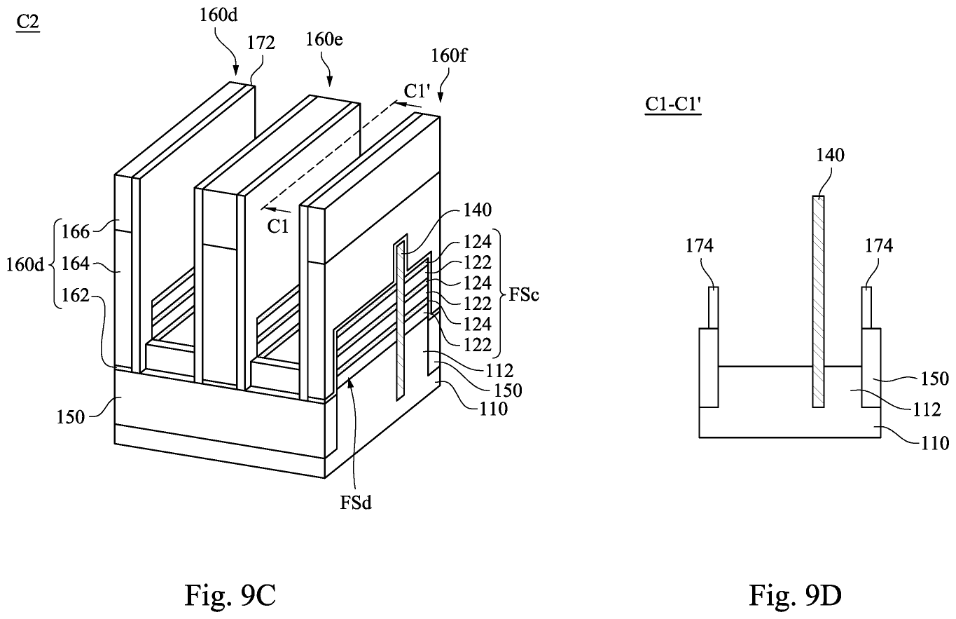

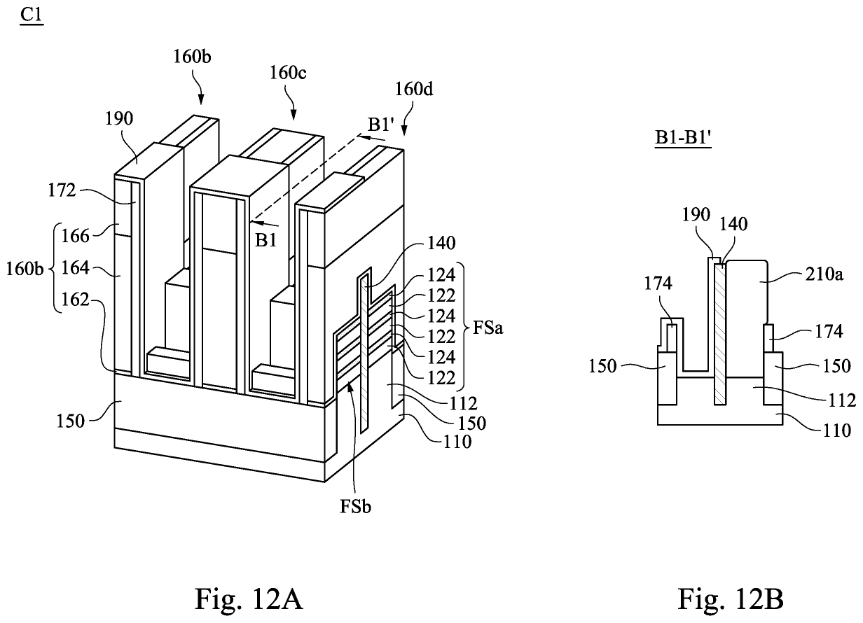

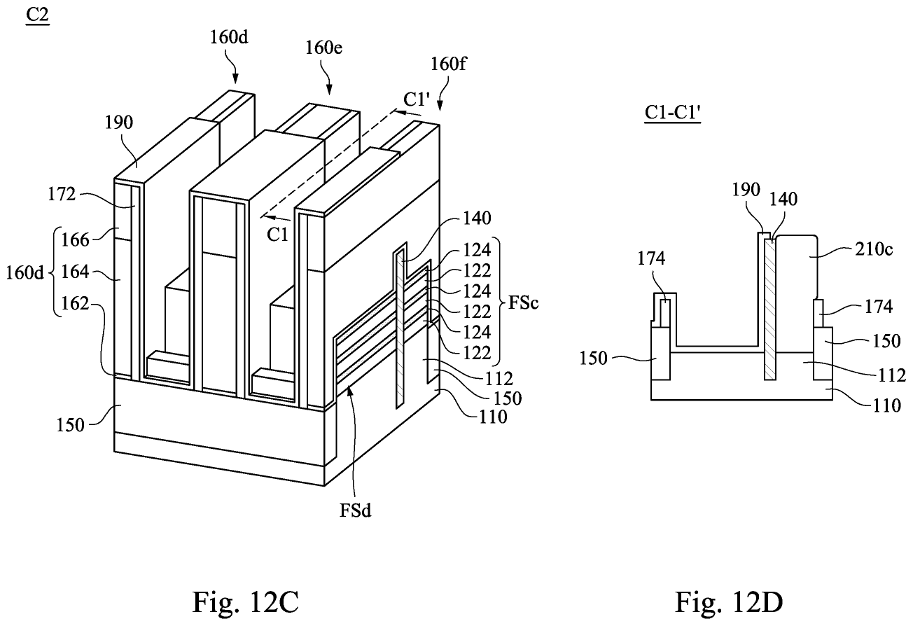

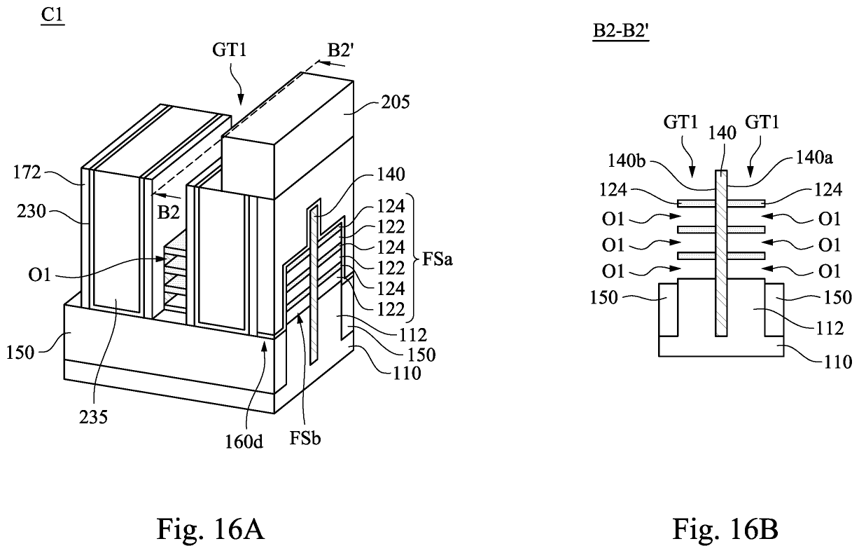

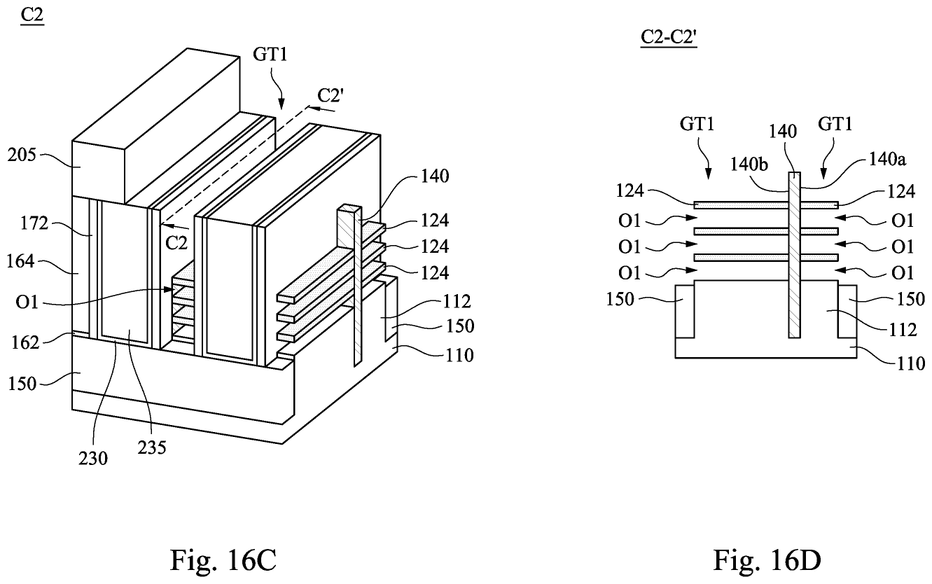

In addition to the integrated circuit structure 100a, FIGS. 2, 3A, 4-9A, 9C, 10A-12A, 12C, 13A-14A, 14C, 15A-16A, 16C, 17A, 17C, 18A, 18C, 19A, 19C, 20A-21A, and 21C depict X-axis, Y-axis, and Z-axis directions. Throughout the various views and illustrative embodiments, like reference numbers are used to designate like elements. It is understood that additional operations can be provided before, during, and after the processes shown by FIGS. 2-21D, and some of the operations described below can be replaced or eliminated, for additional embodiments of the method. The order of the operations/processes may be interchangeable. FIGS. 2, 3A, and 4 are perspective views of area C illustrated in FIG. 1B at intermediate stages during fabrication. FIGS. 5A-9A, 9C, 10A-12A, 12C, 13A-14A, 14C, 15A-16A, 16C, 17A, 17C, 18A, 18C, 19A, 19C, 20A-21A, and 21C are perspective views of area C1 illustrated in FIG. 4 at intermediate stages during fabrication. FIGS. 3B and 3C are cross-sectional views of intermediate stages in the formation of the semiconductor structure 100a obtained from the reference cross-sections B-B′ and C-C′ in FIG. 3A in accordance with some embodiments of the present disclosure. FIGS. 9B, 12B, 14B, 16B, 17B, 18B, 19B, and 21B are cross-sectional views of intermediate stages in the formation of the semiconductor structure 100a obtained from the reference cross-section B1-B1′ in FIGS. 9A, 12A, 14A, and 21A in accordance with some embodiments of the present disclosure. FIGS. 16B, 17B, 18B, and 19B are cross-sectional views of intermediate stages in the formation of the semiconductor structure 100a obtained from the reference cross-section B2-B2′ in FIGS. 16A, 17A, 18A, and 19A in accordance with some embodiments of the present disclosure. FIGS. 9D, 12D, 14D, 16D, 17D, 18D, 19D, and 21D are cross-sectional views of intermediate stages in the formation of the semiconductor structure 100a obtained from the reference cross-section C1-C1′ in FIGS. 9A, 12A. 14A, and 21A in accordance with some embodiments of the present disclosure. FIGS. 16D, 17D, 18D, and 19D are cross-sectional views of intermediate stages in the formation of the semiconductor structure 100a obtained from the reference cross-section C2-C2′ in FIGS. 16A, 17A, 18A, and 19A in accordance with some embodiments of the present disclosure.

As shown in FIG. 1A, in the cell array formed with Fork-Sheet FETs, unit cells 101a and 101b are formed over the substrate 110 as shown in FIG. 2. Some unit cells 101a can have a height H1 that can be at least 1.5 times of the height H2 of other unit cells 101b. This configuration can involve separating regions with the same electrical properties into two unit cells 101b. In this arrangement, only one unit cell 101a can be in the adjacent area with the same electrical properties. By separating regions with the same electrical properties into different unit cells 101b and only one unit cell 101a in the adjacent area, the overall area utilization of the cell array can be improved. This leads to a more efficient use of the available space and contributes to better area scaling. This configuration can allow for greater design flexibility, as it enables individual unit cells in the cell array to optimize performance, and power based on the requirements of the application.

Reference is made to FIGS. 1A, 1B, and 2. A substrate 110 (see FIG. 1A) is provided. In some embodiments, the substrate 110 is made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. Further, the substrate 110 may include an epitaxial layer (epi-layer), which may be strained for performance enhancement, and/or may include a silicon-on-insulator (SOI) structure. In some embodiments, the substrate 110 can be interchangeably referred to as a semiconductor substrate.

The substrate 110 has a first device region 102 (see FIGS. 1B and 2), a second device region 104 (see FIGS. 1B and 2), and a shared border region 106 (see FIGS. 1B and 2) between the first device region 102 and the second device region 104. That is, the first device region 102, the shared border region 106, and the second device region 104 are sequentially arranged in the X direction. The first device region 102 is a region in which first transistors (or first nanostructure devices) will reside, and the second device region 104 is a region in which second transistors (or second nanostructure devices) will reside. In some embodiments, the first transistors are different from the second transistors at least in the device size. For example, first transistors in the first device region 102 may be denser than the second transistors in the second device region 104. The first transistors in the first device region 102 may be applied to some regions of a (e.g., logic) circuit with low current, while the second transistors in the second device region 104 may be applied to some other regions of the circuit with high current (and high computing speed). In some embodiments, different device regions can be configured as columns in the cell array, therefore, the first device region 102 can also be interchangeably referred to a first column of the cell array, and the second device region 104 can also be interchangeably referred to a second column of the cell array.

The first device region 102 and the second device region 104 share a same border region 106, and any number of device features (e.g., other active devices, doped regions, isolation structures, etc.) may be disposed in the first device region 102 and the second device region 104. By contrary, none transistor device or some dummy devices is/are disposed in the shared border region 106. Each of the first device region 102 and the second device region 104 includes at least one first conductivity type region 108 (see FIG. 1B) and at least one second conductivity type region 109 (see FIG. 1B), and the first conductivity type region 108 has an opposite conductivity to the second conductivity type region 109. By way of example and not limitation, the first conductivity type region 108 is a region in which N-type transistors will reside, and the second conductivity type region 109 is a region in which P-type transistors will reside. In some embodiments, the first conductivity type region 108 is a region in which P-type transistors will reside, and the second conductivity type region 109 is a region in which N-type transistors will reside.

As shown in FIG. 2, a semiconductor stack 120 is formed on the substrate 110 through epitaxy, such that the semiconductor stack 120 forms crystalline layers. The semiconductor stack 120 includes semiconductor layers 122 and 124 stacked alternatively. There may be two, three, four, or more of the semiconductor layers 122 and 124. The semiconductor layers 122 may be SiGe layers. The semiconductor layers 124 may be pure silicon layers that are free from germanium. The semiconductor layers 124 may also be substantially pure silicon layers, for example, with a germanium percentage lower than about 1 percent. Furthermore, the semiconductor layers 124 may be intrinsic, which are not doped with p-type and n-type impurities. In some other embodiments, however, the semiconductor layers 124 can be silicon germanium or germanium for p-type semiconductor device, or can be III-V materials, such as InAs, InGaAs, InGaAsSb, GaAs, InPSb, or other suitable materials.

The semiconductor layers 124 or portions thereof may form nanostructure channel(s) of nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are fork-sheets, nanosheets, nanowires, nanoslabs, or nanorings, depending on their geometry. The use of the semiconductor layers 124 to define a channel or channels of the semiconductor device is further discussed below. In some embodiments, the semiconductor layer 124 can be interchangeably referred to as a channel region, a channel pattern, a channel structure, a nanostructure, or a semiconductor sheet.

As described above, the semiconductor layers 124 may serve as channel region(s) for a subsequently-formed semiconductor device and the thickness is chosen based on device performance considerations. The semiconductor layers 122 in channel regions(s) may eventually be removed and serve to define a vertical distance between adjacent channel region(s) for a subsequently-formed multi-gate device and the thickness is chosen based on device performance considerations. Accordingly, the semiconductor layers 122 may also be referred to as sacrificial layers, and the semiconductor layers 124 may also be referred to as channel layers.

A patterned hard mask 130 is formed over the semiconductor stack 120. The patterned hard mask 130 covers portions of the semiconductor stack 120 while leave another portions of the semiconductor stack 120 uncovered. In some examples, the patterned hard mask 130 is deposited on the semiconductor stack 120 by thermally grown process, chemical vapor deposition (CVD) process, and/or atomic layer deposition (ALD) process. In FIG. 2, the patterned hard mask 130 includes hard masks 132, 134, 136, and 138. The hard masks 132 and 134 are respectively disposed on the first conductivity type regions 108 (see FIG. 1B) to define N-type active regions thereon over the first and second device region 102 and 104. The hard masks 136 and 138 are respectively disposed on the second conductivity type regions 109 (see FIG. 1B) to define P-type active regions thereon over the first and second device region 102 and 104. As shown in FIG. 2, the hard mask 134 has a same dimension in the Y direction over the second device region 104 as the hard masks 132 over the first device region 102, and the hard mask 138 has a greater dimension in Y direction over the second device region 104 than the hard mask 136 over the first device region 102.

Reference is made to FIGS. 1A, 1B, and 3A-3C. The semiconductor stack 120 and the substrate 110 of FIG. 2 are patterned using the patterned hard mask 130 as etching masks to form trenches Ta, Tb, Tc, and Td. Accordingly, a plurality of fin structures (or semiconductor strips or active regions) FSa, FSb, FSc, and FSd are formed. The trenches Ta. Tb. Tc, and Td extend into the substrate 110 and have lengthwise directions substantially parallel to each other. The trenches Ta, Tb, Tc, and Td form protrusion structures 112 in the substrate 110, where the protrusion structures 112 protrude from the substrate 110, and the fin structures FSa, FSb, FSc. and FSd are respectively formed above the protrusion structures 112 of the substrate 110. The remaining portions of the semiconductor stack 120 are accordingly referred to as the fin structures FSa, FSb, FSc. and FSd alternatively.

The fin structures FSa and FSb are patterned by using the hard masks 132 and 136 as etching masks, and the fin structures FSc and FSd are patterned by using the hard masks 134 and 138 as the etching mask. As shown in FIGS. 3A and 3B, the fin structures FSa and FSb are formed over the first device region 102. Specifically, the fin structures FSa are formed over the first conductivity type regions 108, respectively, and the fin structures FSb are formed over the second conductivity type region 109, respectively. The fin structure FSa has a width W13 (see FIG. 3B), the fin structure FSb has a width W14 (see FIG. 3B), and the width W13 is substantially the same as the width W14. In some embodiments, the width W13 of the fin structure FSa can be different form the width W14 of the fin structure FSb. By way of example and not limitation, the width W13 of the fin structure FSa can be greater than or less the width W14 of the fin structure FSb. In FIGS. 3A and 3B, the trenches Tb are defined by the adjacent fin structure FSa and FSb and each of the trenches Tb has a width W11 in the Y direction. The trench Ta is defined by the adjacent fin structures FSa or by the adjacent fin structures FSb, and the trench Ta has a width W12 in the Y direction. The width W12 of trench Ta is greater than the width W11 of trench Tb.

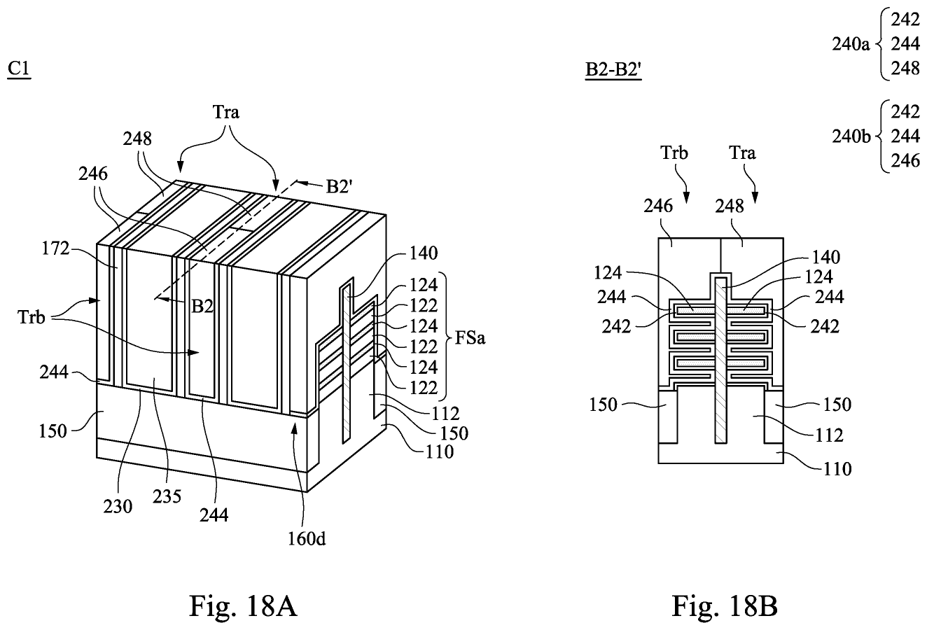

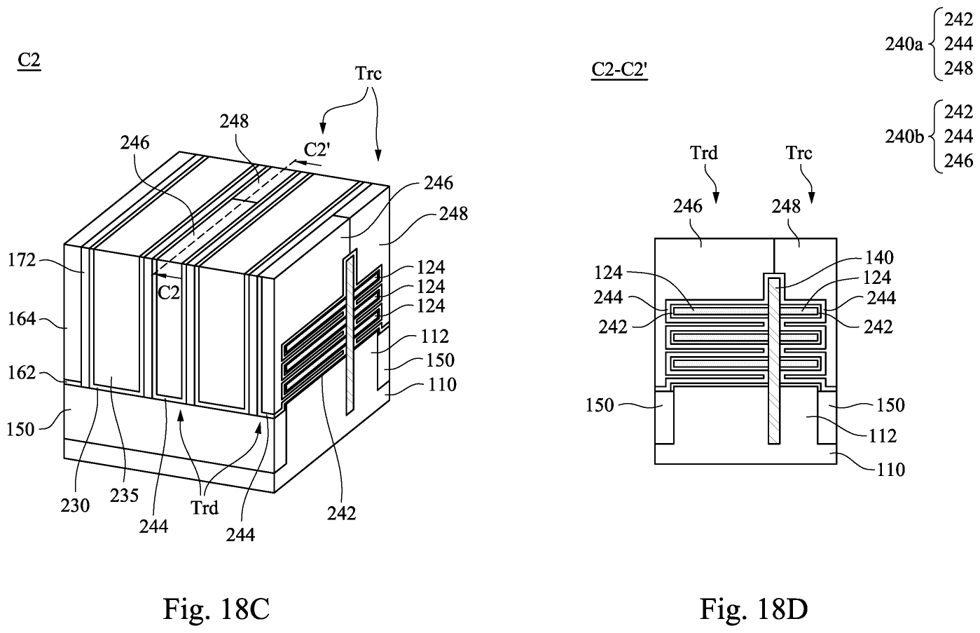

As shown in FIGS. 3A and 3C, the fin structures FSc and FSd are formed over the second device region 104 (see FIG. 3A). Specifically, the fin structure FSc is formed over the first conductivity type regions 108, and the fin structure FSd is formed over the second conductivity type region 109. The fin structure FSc has a width W23 (see FIG. 3C), the fin structure FSd has a width W24 (see FIG. 3C), and the width W24 is greater than the width W23 of the fin structure FSc, the width W13 of the fin structure FSa, and the width W14 of the fin structure FSb of the fin structure FSb, and thus transistor Trd (see FIGS. 18C and 18D) in the unit cell 101a (see FIG. 1A) can have a greater channel width (or device size) than other transistors. The widths W11, W12. W13, W14, W21, W22, W23, and W24 are dimensions extending in the lengthwise direction of the gate structures 160a-160g as shown in FIG. 1B. In some embodiments, the width W24 of the fin structure FSd is grater other widths of the fin structures in the first device region 102. By way of example and not limitation, the width W24 may be greater than any one of the widths W13, W14, and W23 about 1.5 times, such as about 1.5, 2, 2.5, 3, 3.5, 4, 4.5, 5, 5.5, 6, 6.5, 7, 7.5, 8, 8.5, 9, 7.5, or 10 times. A greater channel width in the transistor can provide higher drive current, improving the overall performance of the semiconductor device. This is beneficial for applications that require rapid switching or driving large capacitive loads. In addition, a greater channel width can improve energy efficiency and reduced power consumption. Furthermore, the capability to vary the channel width of the Fork-Sheet FET within the enlarged unit cell can optimize transistor characteristics based on the requirements of the application. This provides greater flexibility in adjusting performance and power trade-offs in the semiconductor device. In some embodiments, at least one of the fin structures in the second device region 104 (or second column of the cell array) can have a greater width than all of the fin structures in the first device region 102 (or first column of the cell array).

In FIGS. 3A and 3C, the trenches Tc are defined by the adjacent fin structures FSc and FSd and each of the trenches Tc has a width W21 (see FIG. 3C) in the Y direction. The trench Td is defined by the adjacent fin structures FSc or by the adjacent fin structures FSd, and the trench Td has a width W22 in the Y direction. The width W22 of trench Td is greater than the width W21 of trench Tc.

Reference is made to FIGS. 1A, 1B, and 4. A dielectric film 140′ is formed on the fin structures FSa-FSd (see FIGS. 3A-3C) and the patterned hard mask 130 (see FIGS. 3A-3C). For example, the dielectric film 140′ is conformally deposited on the structure illustrated in FIG. 3A using CVD, ALD, or suitable methods. The dielectric film 140′ lines sidewalls and bottom surfaces of the trenches Ta-Td (see FIGS. 3A-3C). The dielectric film 140′ includes dielectric materials. In some embodiments, the dielectric film 140′ includes SiO₂, SiN, SiCN, SiCON, SiCO, AlO, HfO, other high-k dielectric materials, combinations thereof, multiple layers thereof, or the like.

Due to width differences among the trenches Ta-Td (see FIGS. 3A-3C), the dielectric film 140′ completely fills the trenches Ta and Tc, which are narrower than the trenches Tb and Td, but does not completely fill the trenches Tb and Td. In the example where the formation of the dielectric film 140′ is a conformal process, a seam may be formed within the dielectric film 140′ by virtue of the conformal process and high aspect ratio of the trenches Ta and Tc. For example, the dielectric film 140′ can have lateral growth fronts in the trenches Ta and Tc (e.g., proceeding laterally from sidewalls of respective fin structures FSa-FSd) that merge together. The merging of the lateral growth fronts can create the seam in the dielectric film 140′ between neighboring fin structures FSa-FSd.

Reference is made to FIGS. 1A, 1B, 5A, and 5B. Subsequently, the example process etches back the dielectric film 140′ (FIG. 4) to remove portions of the dielectric film 140′ in the trenches Ta and Tc and completely remove the dielectric film 140′ from the trenches Tb and Td. In some embodiments, the dielectric film 140′ may be etched back in a dry etching process that uses oxygen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Unlike the narrower trenches Ta and Tc which are entirely filled by the dielectric film 140′, the wider trenches Tb and Td allow etchant to etch sidewalls and bottom surfaces of the dielectric film 140′ from inside the trenches Tb and Td, such that the dielectric film 140′ is removed from the wider trenches Tb and Td in a faster rate than from the narrower trenches Ta and Tc. As shown in FIGS. 5A and 5B, the dielectric film 140′ is removed from the wider trenches Tb and Td, while the dielectric film 140′ collectively define dielectric fins 140 in the narrower trenches Ta and Tc, respectively. The dielectric fin 140 each has a top at a height between a top of the patterned hard mask 130 and a top of the fin structures FSa-FSd. The dielectric fin 140 each is between two neighboring fin structures FSa-FSb or FSc-FSd. For example, the dielectric fin 140 is in contact with the fin structures FSa, FSb, FSc, and FSd. The dielectric fins 140 can extend in parallel with each other. In some embodiments, the dielectric fin 140 can be interchangeably referred to an isolation wall, an isolation strip, an isolation line, or an isolation pattern.

Reference is made to FIGS. 1A, 1B. 6A, and 6B. Isolation structures 150, such as shallow trench isolations (STI), are disposed in the trenches Tb and Td and over the substrate 110. The isolation structures 150 can be equivalently referred to as an isolation insulating layer in some embodiments. The isolation structures 150 may be made of suitable dielectric materials such as silicon oxide, silicon nitride, silicon oxynitride, fluorine-doped silicate glass (FSG), low-k dielectrics such as carbon doped oxides, extremely low-k dielectrics such as porous carbon doped silicon dioxide, a polymer such as polyimide, combinations of these, or the like. In some embodiments, the isolation structures 150 are formed through a process such as CVD, flowable CVD (FCVD), or a spin-on-glass process, although any acceptable process may be utilized. Subsequently, portions of the isolation structures 150 extending over the top surfaces of the fin structures FSa-FSd, are removed using, for example, an etching back process, chemical mechanical polishing (CMP), or the like.

The isolation structures 150 are then recessed to expose the patterned hard mask 130. In some embodiments, the isolation structures 150 are recessed using a single etch processes, or multiple etch processes. In some embodiments in which the isolation structures 150 is made of silicon oxide, the etch process may be, for example, a dry etch, a chemical etch, or a wet cleaning process. For example, the chemical etch may employ fluorine-containing chemical such as dilute hydrofluoric (dHF) acid. In some embodiments, the space defined by isolation structure 150 can be called an isolation space.

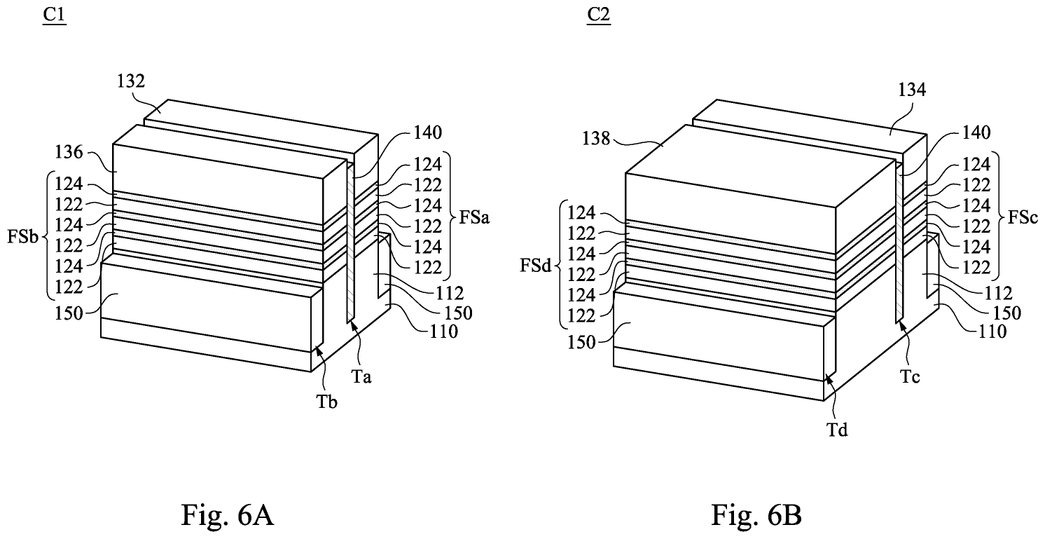

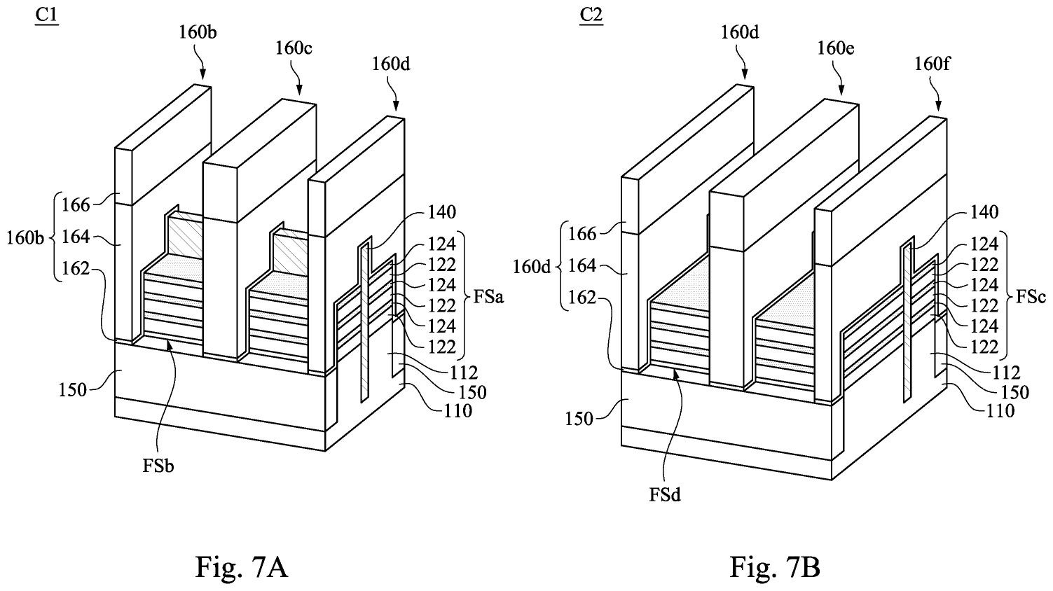

Reference is made to FIGS. 1A, 1B, 7A, and 7B. The patterned hard mask 130 (see FIGS. 6A and 6B) is removed by using one or more etching processes. Dummy gate structures 160a, 160b, 160c, 160d, 160e. 160f, and 160g are formed over the substrate 110 and are at least partially disposed over the fin structures FSa-FSd. The dummy gate structures 160a-160g can extend in parallel with each other. The portions of the fin structures FSa-FSd underlying the dummy gate structures 160a-160g may be referred to as the channel regions. The dummy gate structures 160a-160g may also define source/drain (S/D) regions of the fin structures FSa-FSd for example, the regions of the fin structures FSa-FSd adjacent and on opposing sides of the channel regions. In some embodiments, the dummy gate structure can be interchangeably referred to as a dummy gate strip, a dummy gate pattern, a dummy gate layer, or a dummy gate.

The dummy gate structures 160a, 160b, and 160c are formed in the first device region 102, the dummy gate structure 160d is formed between the first device region 102 and the shared border region 106, the dummy gate structure 160e, 160f, and 160g are formed in the second device region 104. In some embodiments, the dummy gate structures 160a-160g can have a constant pitch.

Dummy gate formation operation first forms a dummy gate dielectric layer 162 over the fin structures FSa-FSd. Subsequently, a dummy gate electrode layer (or semiconductive gate layer or a polysilicon gate layer) 164 and a hard mask 166 are formed over the dummy gate dielectric layer 162. The dummy gate electrode layer 164 is patterned by using the patterned hard mask 166 as an etch mask. In some embodiments, after patterning the dummy gate electrode layer 164, the dummy gate dielectric layer 162 is removed from the S/D regions of the fin structures FSa-FSd. The etch process may include a wet etch, a dry etch, and/or combinations thereof. The etch process is chosen to selectively etch the dummy gate dielectric layer 162 without substantially etching the fin structures FSa-FSd, the dummy gate electrode layer 164, and the hard mask 166. Therefore, each of the dummy gate structures (or semiconductive gate structures or a polysilicon gate structures) 160a-160g includes the dummy gate dielectric layer 162, the dummy gate electrode layer 164, and the hard mask 166. As shown in FIG. 1B, in the second device region 104, the dummy gate structures 160e-160g may overlap solely with the dielectric fin 140 extending from the adjacent first device region 102, rather than overlapping with another dielectric fin 140 originating from the same adjacent first device region 102. In other words, different dielectric fins 140 can have different lengths. For example, the dielectric fin 140 not covered by the dummy gate structures 160a-160c can be of shorter length than the dielectric fin 140 covered by the dummy gate structures 160e-160g from the top view.

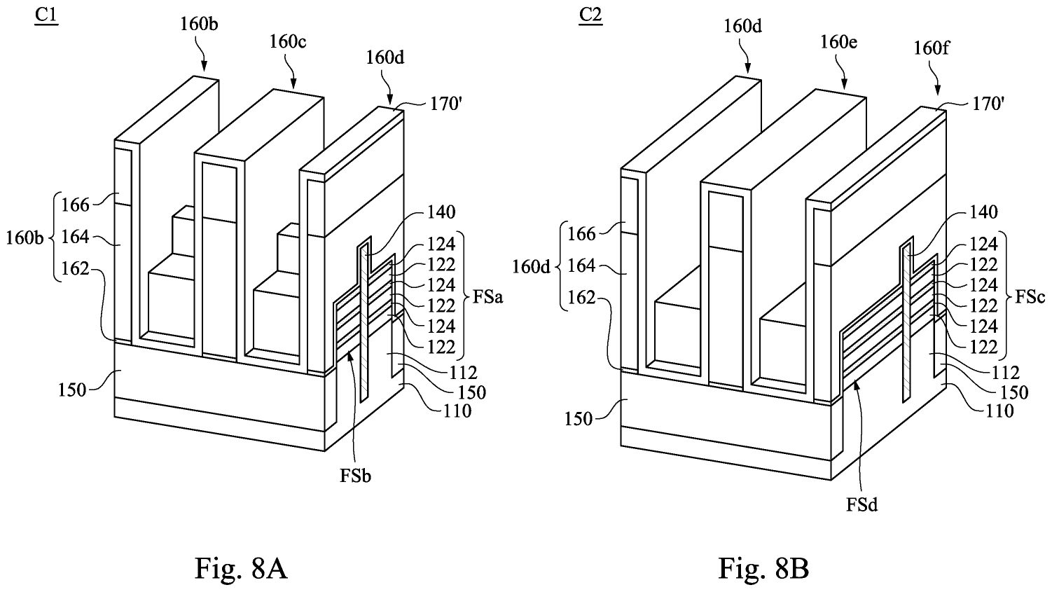

Reference is made to FIGS. 1A, 1B, 8A, and 8B. After formation of the dummy gate structures 160a-160g is completed, gate spacers 172 (see FIGS. 9A and 9C) are formed on sidewalls of the dummy gate structures 160a-160g. Specifically, as shown in FIGS. 8A and 8B, a dielectric film 170′ is deposited on the structure as illustrated in FIGS. 7A and 7B. The dielectric film 170′ may be silicon nitride (SiN), silicon carbonoxide (SiCO), silicon carbonnitride (SiCN), silicon oxycarbonnitride (SiOCN), or the like. The dielectric film 170′ is conformally formed on the substrate 110, the dummy gate structures 160a-160f, and the fin structures FSa-FSd. In some embodiments, the dielectric film 170′ may be a single layer or multiple layers.

Reference is made to FIGS. 1A, 1B, and 9A-9D. An anisotropic etching process is then performed on the deposited dielectric film 170′ (see FIGS. 8A and 8B) to expose portions of the fin structures FSa-FSd not covered by the dummy gate structure 160a-160g (e.g., in source/drain regions of the fin structures FSa-FSd). Portions of the dielectric materials directly above the dummy gate structures 160a-160g may be completely removed by this anisotropic etching process. Portions of the dielectric materials on sidewalls of the dummy gate structures 160a-160g may remain, forming gate sidewall spacers, which are denoted as the gate spacers 172, for the sake of simplicity.

The anisotropic etching process further etches exposed portions of the fin structures FSa-FSd that extend laterally beyond the gate spacers 172 (e.g., in the source/drain regions of the fin structures FSa-FSd), resulting in recesses R1 into the fin structures FSa-FSd and between corresponding dummy gate structures 160a-160g. After the anisotropic etching, end surfaces of the semiconductor layers 122 and 124 are aligned with respective outermost sidewalls of the gate spacers 172, due to the anisotropic etching. In some embodiments, the protrusion structures 112 are also recessed as shown in FIGS. 9A-9D. In still some embodiments, the dielectric fins 140 are also recessed as shown in FIGS. 9A and 9C.

In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

Further, sidewall spacers 174, which are remaining parts of the dielectric film 170′ that are not removed in the operation of the anisotropic etching process, exist. Specifically, when the dielectric film 170′ is etched to form the gate spacers 172, portions of the dielectric film 170′ on sidewalls of the fin structures FSa-FSd are pullback-etched. Portions of the dielectric film 170′ thus remain at corners between the isolation structure 150 and the fin structures FSa-FSd after the etching and form the sidewall spacers 174. On the other hand, due to the presence of the dielectric fins 140, sidewall spacers 174 may not be formed over the shared border region 106.

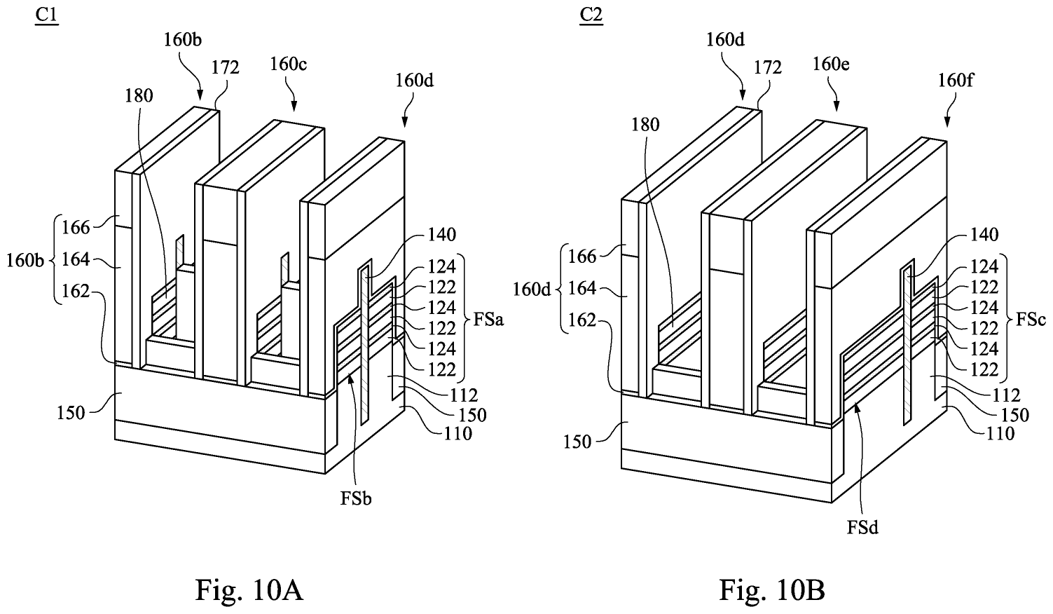

Reference is made to FIGS. 1A, 1B, 10A, and 10B. The semiconductor layers 122 are laterally or horizontally recessed by using suitable etch techniques, resulting in lateral recesses each vertically between corresponding semiconductor layers 124. This operation may be performed by using a selective etching process. By way of example and not limitation, the semiconductor layers 122 are SiGe and the semiconductor layers 124 are silicon allowing for the selective etching of the semiconductor layers 122. In some embodiments, the selective wet etching includes an APM etch (e.g., ammonia hydroxide-hydrogen peroxide-water mixture) that etches SiGe at a faster etch rate than it etches Si. As a result, the semiconductor layers 124 laterally extend past opposite end surfaces of the semiconductor layers 122.

Inner spacers 180 are then formed in the recesses. For example, an inner spacer material layer is formed to fill the recesses left by the lateral etching of the semiconductor layers 122. The inner spacer material layer may be a low-k dielectric material, such as SiO₂, silicon nitride (SiN), silicon carbonoxide (SiCO), silicon carbonnitride (SiCN), silicon oxycarbonnitride (SiOCN). The inner spacer material layer can be formed using CVD, including LPCVD and PECVD, PVD, ALD, or other suitable processes. After the deposition of the inner spacer material layer, an anisotropic etching process is performed to trim the deposited inner spacer material layer, such that portions of the deposited inner spacer material layer that fill the recesses left by the lateral etching of the semiconductor layers 122 are left. After the trimming process, the remaining portions of the deposited inner spacer material are denoted as the inner spacers 180 for the sake of simplicity. The inner spacers 180 serve to isolate metal gates from source/drain epitaxial structures formed in subsequent processing. In the example of FIGS. 10A and 10B, sidewalls of the inner spacers 180 are substantially aligned with sidewalls of the channel layers 124.

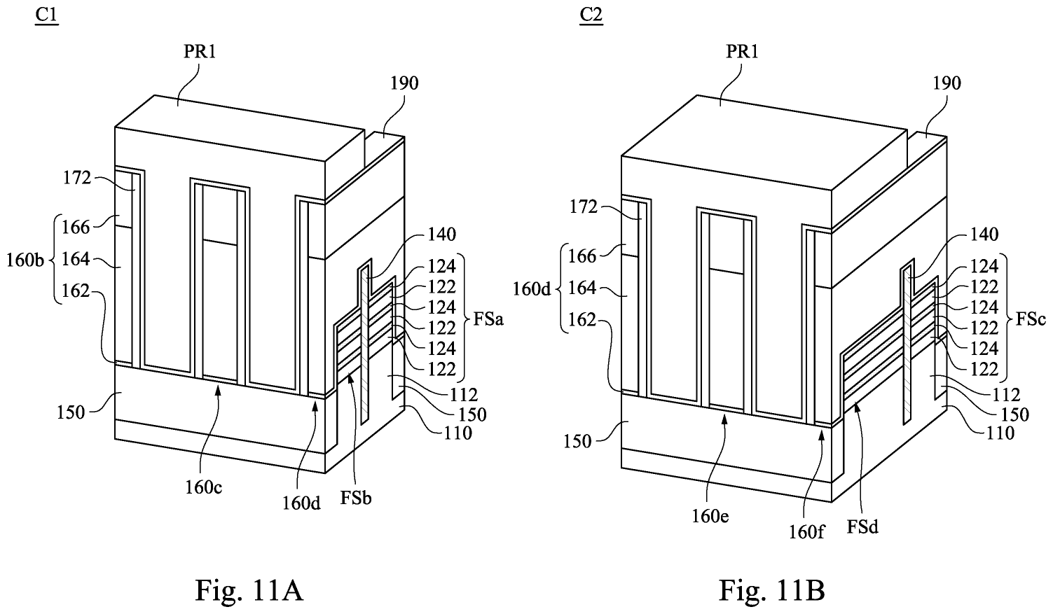

Reference is made to FIGS. 1A, 1B, 11A, and 11B. A protection layer 190 is conformally deposited on the structure illustrated in FIGS. 10A and 10B. In some embodiments, the protection layer 190 is made of a dielectric material, e.g., silicon oxide, silicon nitride, SiCON, high-k dielectric materials, combinations thereof, or the like. Subsequently, a photoresist layer PR1 is deposited over the protection layer 190. The photoresist layer PR1 is then patterned to expose portions of the protection layer 190 directly over the first conductivity type regions 108 (see FIGS. 1A and 1B) of the substrate 110.

Reference is made to FIGS. 1A, 1B, and 12A-12D. The protection layer 190 is then patterned by using the photoresist layer PR1 (see FIGS. 11A and 11B) as an etch mask, such that the protection layer 190 exposes the structure over the first conductivity type regions 108 (see FIGS. 1A and 1B) of the substrate 110. The photoresist layer PR1 is then removed by using, for example, etching or ashing process.

Source/drain epitaxial structures 210a, 210c (see FIGS. 12B and 12D) are formed at the source/drain regions of the fin structures FSa and FSc (see FIGS. 12A and 12C). The source/drain epitaxial structures 210a and 210c are connected to the semiconductor layers 124. The source/drain epitaxial structures 210a and 210c are formed over the first device region 102 and the second device region 104 (see FIGS. 1A and 1B), respectively. The source/drain epitaxial structures 210a and 210c may be formed by performing an epitaxial growth process that provides an epitaxial material connected to the fin structures FSa and FSc. During the epitaxial growth process, the dummy gate structures 160a-160g, the gate spacers 172, the sidewall spacers 174, and the protection layer 190 limit the source/drain epitaxial structures 210a and 210c to the source/drain regions. In some embodiments, the lattice constants of the source/drain epitaxial structures 210a and 210c are different from the lattice constant of the semiconductor layers 124, so that the semiconductor layers 124 can be strained or stressed by the source/drain epitaxial structures 210a and 210c to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor layers 124.

In some embodiments, the source/drain epitaxial structures 210a and 210c may include Ge, Si, GaAs, AlGaAs, SiGe, GaAsP, SiP, or other suitable material. The source/drain epitaxial structures 210a and 210c may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 210a and 210c are not in-situ doped, an implantation process (i.e., a junction implant process) is performed to dope the source/drain epitaxial structures 210a and 210c. In some exemplary embodiments, the source/drain epitaxial structures 210a and 210c in an n-type include Si:P. In some embodiments, the source/drain epitaxial structures 210a and 210c can be interchangeably referred to as source/drain regions, source/drain patterns, or source/drain structures.

Reference is made to FIGS. 1A, 1B. 13A and 13B. The protection layer 190 (see FIGS. 12A-12D) is then removed by using, for example, etching process. Subsequently, another protection layer 195 is conformally deposited over the substrate 110, and another photoresist layer PR2 is deposited on the protection layer 195. The protection layer 195 is made of a material similar to or the same as the protection layer 190. The photoresist layer PR2 is then patterned to expose portions of the protection layer 195 directly over the second conductivity type regions 109 of the substrate 110.

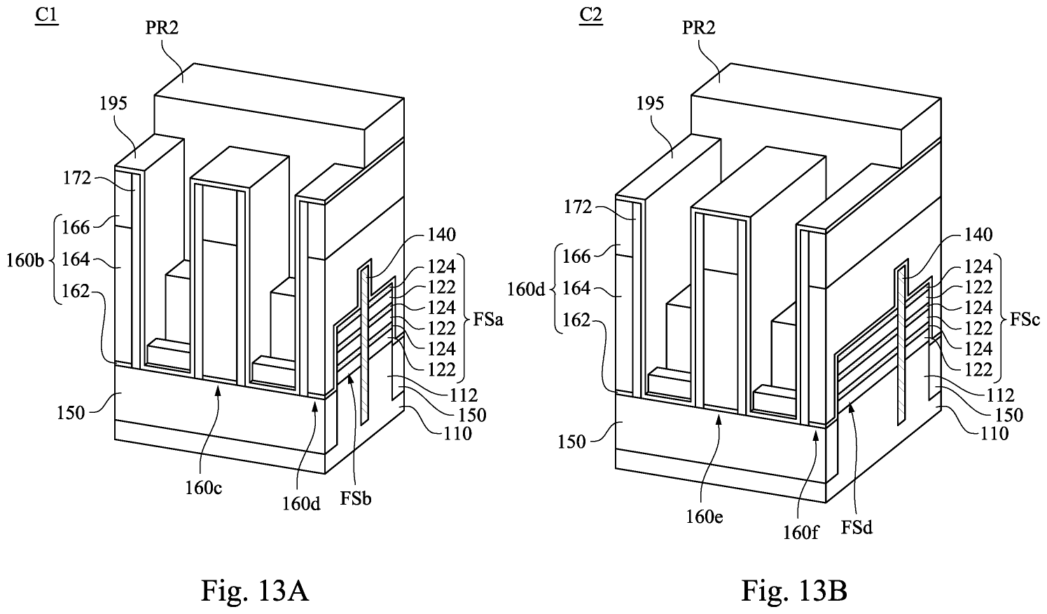

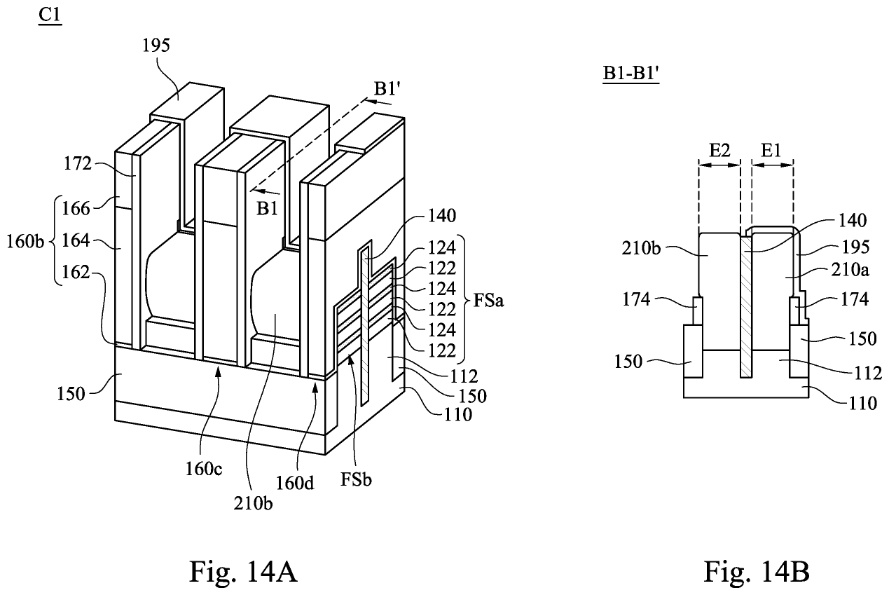

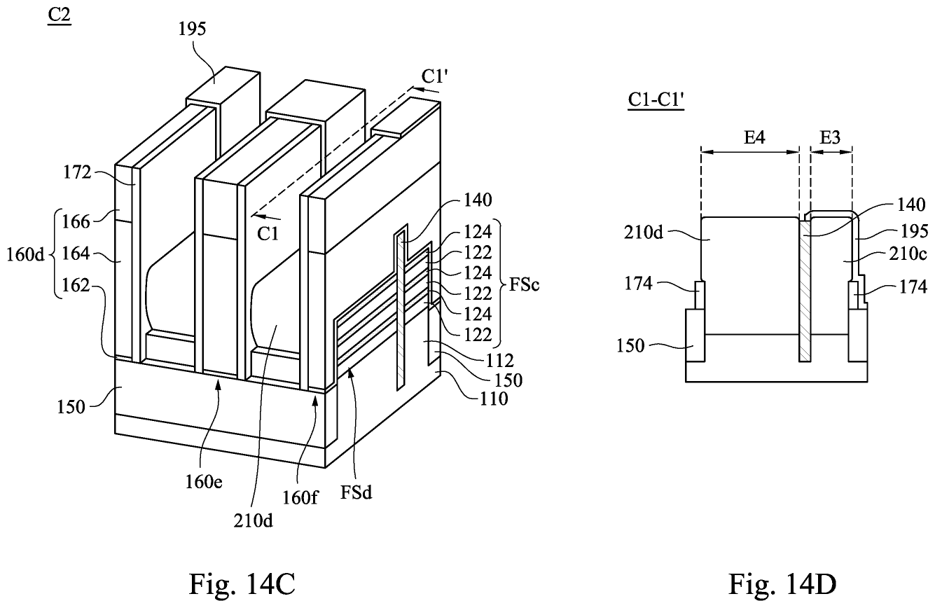

Reference is made to FIGS. 1A, 1B, and 14A-14D. Similarly, the protection layer 195 is patterned by using the photoresist layer PR2 (see FIGS. 13A and 13B) as an etch mask, such that the protection layer 195 exposes the structure over the second conductivity type regions 109 of the substrate 110. The photoresist layer PR2 is then removed by using, for example, etching or ashing process.

Source/drain epitaxial structures 210b and 210d are formed over the source/drain regions of the fin structures FSb and FSd. The source/drain epitaxial structures 210b and 210d are connected to the semiconductor layers 124. The source/drain epitaxial structures 210b and 210d are formed over the first device region 102 and the second device region 104 (see FIG. 1B), respectively. The source/drain epitaxial structures 210b and 210d may be formed by performing an epitaxial growth process that provides an epitaxial material on the fin structures FSb and FSd. During the epitaxial growth process, the dummy gate structures 160a-160g, the gate spacers 172, the sidewall spacers 174, and the protection layer 195 limit the source/drain epitaxial structures 210b and 210d to the source/drain regions. In some embodiments, the lattice constants of the source/drain epitaxial structures 210b and 210d are different from the lattice constant of the semiconductor layers 124, so that the semiconductor layers 124 can be strained or stressed by the source/drain epitaxial structures 210b and 210d to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor layers 124.

In some embodiments, the source/drain epitaxial structures 210b and 210d may include Ge. Si, GaAs, AlGaAs, SiGe, GaAsP. SiP, or other suitable material. The source/drain epitaxial structures 210b and 210d may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 210b and 210d are not in-situ doped, an implantation process (i.e., a junction implant process) is performed to dope the source/drain epitaxial structures 210b and 210d. In some exemplary embodiments, the source/drain epitaxial structures 210b and 210d in a p-type include SiGeB and/or GeSnB. In some embodiments, the source/drain epitaxial structures 210b and 210d can be interchangeably referred to as source/drain regions, source/drain patterns, or source/drain structures.

As shown in FIGS. 14B and 14D, the source/drain epitaxial structure 210a has a width E1, the source/drain epitaxial structure 210b has a width E2, the source/drain epitaxial structure 210c has a width E3, and the source/drain epitaxial structure 210d has a width E4 greater than the widths E1-E3, and thus and thus transistor Trd (see FIGS. 18A and 18B) in the unit cell 101a (see FIG. 1A) can have a greater source/drain region width than other transistors. A greater source/drain region width can provide a higher drive current, which improves the overall performance of the semiconductor device. This is beneficial for applications that require rapid switching or driving large capacitive loads. In addition, a greater source/drain region width can reduce the series resistance between the source/drain region and the channel region, resulting in lower power dissipation and improved energy efficiency during device operation. Furthermore, the ability to vary the source/drain region width of the Fork-Sheet FET within the enlarged unit cell enables to optimize transistor characteristics based on the requirements of the application. This provides greater flexibility in adjusting performance and power trade-offs in the semiconductor device.

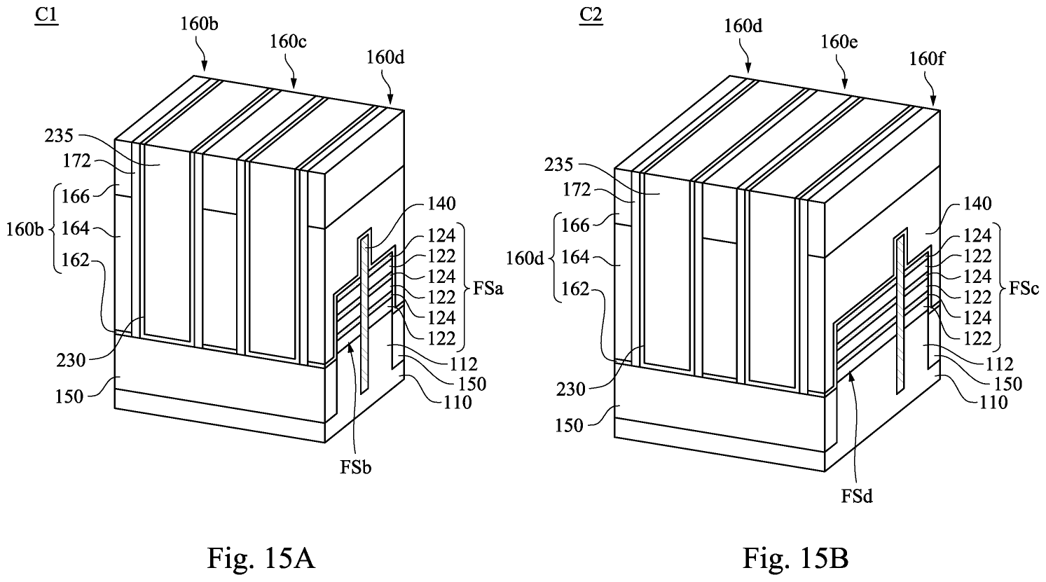

Reference is made to FIGS. 1A, 1B, 15A, and 15B. The protection layer 195 (see FIGS. 14A-14D) is then removed by using, for example, etching process. A contact etch stop layer (CESL) 230 is conformally formed over the substrate 110. In some embodiments, the CESL 230 can be a stressed layer or layers. In some embodiments, the CESL 230 has a tensile stress and is formed of SiN, SiCN, combinations thereof, of the like. In some other embodiments, the CESL 230 includes materials such as oxynitrides. In yet some other embodiments, the CESL 230 may have a composite structure including a plurality of layers, such as a silicon nitride layer overlying a silicon oxide layer. The CESL 230 can be formed using plasma enhanced CVD (PECVD), however, other suitable methods, such as low-pressure CVD (LPCVD), atomic layer deposition (ALD), and the like, can also be used.

An interlayer dielectric (ILD) layer 235 is then formed on the CESL 230. The ILD layer 235 may be formed by chemical vapor deposition (CVD), high-density plasma CVD, spin-on, sputtering, or other suitable methods. In some embodiments, the ILD layer 235 includes silicon oxide. In some other embodiments, the ILD layer 235 may include silicon oxy-nitride, silicon nitride, SiOCN, compounds including Si, O, C and/or H (e.g., silicon oxide, SiCOH and SiOC), a low-k material, or organic materials (e.g., polymers). After the ILD layer 235 is formed, a planarization operation, such as CMP, is performed, so that the patterned hard masks 166 (see FIGS. 14A and 14C) are removed and the dummy gate electrode layers 164 are exposed.

Reference is made to FIGS. 1A, 1B, and 16A-16D. A mask layer 205 is formed over the substrate 110 and covers the dummy gate structure 160d. The dummy gate electrode layers 164 and the dummy gate dielectric layers 162 of the dummy gate structures 160a, 160b, 160c, 160e, 160f, and 160g (see FIGS. 15A and 15B) are then removed, thereby exposing the semiconductor layers 122 and 124. The ILD layer 235 protects the source/drain epitaxial structures 210a-210d during the removal of the dummy gate electrode layers 164 and the dummy gate dielectric layers 162. In some embodiments, the dummy gate electrode layers 164 and the dummy gate dielectric layers 162 are removed by using a selective etching process (e.g., selective dry etching, selective wet etching, or combinations thereof) that etches the materials in dummy gate electrode layers 164 and the dummy gate dielectric layers 162 at a faster etch rate than it etches other materials (e.g., the gate spacers 172 and/or the ILD layer 235), thus resulting in gate trenches GT1 between corresponding gate spacers 172, with the semiconductor layers 122 and 124 exposed in the gate trenches GT1. Subsequently, the semiconductor layers 122 in the gate trenches GT1 are removed by using another selective etching process that etches the semiconductor layers 122 at a faster etch rate than it etches the semiconductor layers 124, thus forming openings O1 between neighboring semiconductor layers (i.e., channel layers) 124. In this way, the semiconductor layers 124 become nanosheets suspended over the substrate 110 and between the source/drain epitaxial structures 210a-210d. This operation is also called a channel release process. In some embodiments, the semiconductor layers 124 can be interchangeably referred to as nanostructure (fork-sheets, nanowires, nanoslabs and nanorings, nanosheet, etc., depending on their geometry). For example, in some other embodiments the semiconductor layers 124 may be trimmed to have a substantial rounded shape (i.e., cylindrical) due to the selective etching process for completely removing the semiconductor layers 122. In that case, the resultant semiconductor layers 124 can be called nanowires.

As shown in FIG. 16B, a first group of the semiconductor layers 124 laterally extends from a sidewall 140a of the dielectric fin 140 and arranged in the vertical direction, and a second group of the semiconductor layers 124 laterally extends from a sidewall 140b of the dielectric fin 140 opposing the sidewall 140a and arranged in the vertical direction. The dielectric fin 140 is in contact with the first and second groups of the semiconductor layers 124. As shown in FIG. 16D, a third group of the semiconductor layers 124 laterally extends from the sidewall 140a of the dielectric fin 140 and arranged in the vertical direction, and a fourth group of the semiconductor layers 124 laterally extends from the sidewall 140b of the dielectric fin 140 opposing the sidewall 140a and arranged in the vertical direction. The dielectric fin 140 is in contact with the third and fourth groups of the semiconductor layers 124. In other words, the dielectric fin 140 interpose the first group of the semiconductor layers 124 and the second group of the semiconductor layers 124 and further continuously extends to interpose the third and fourth groups of the semiconductor layers 124. To put it another way, the isolation wall 140 in the second device region 104 has a longitudinal end in contact with a longitudinal end of the isolation wall in the first device region 102.

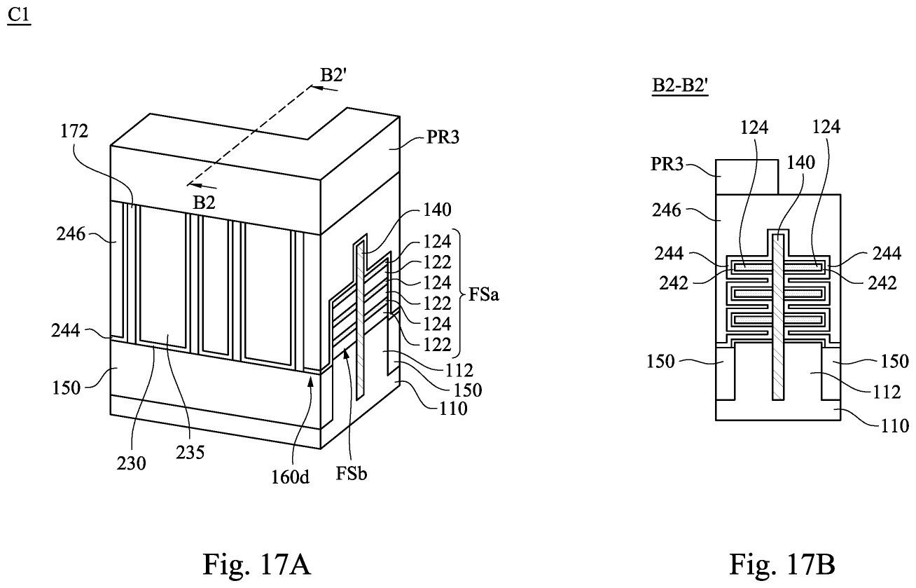

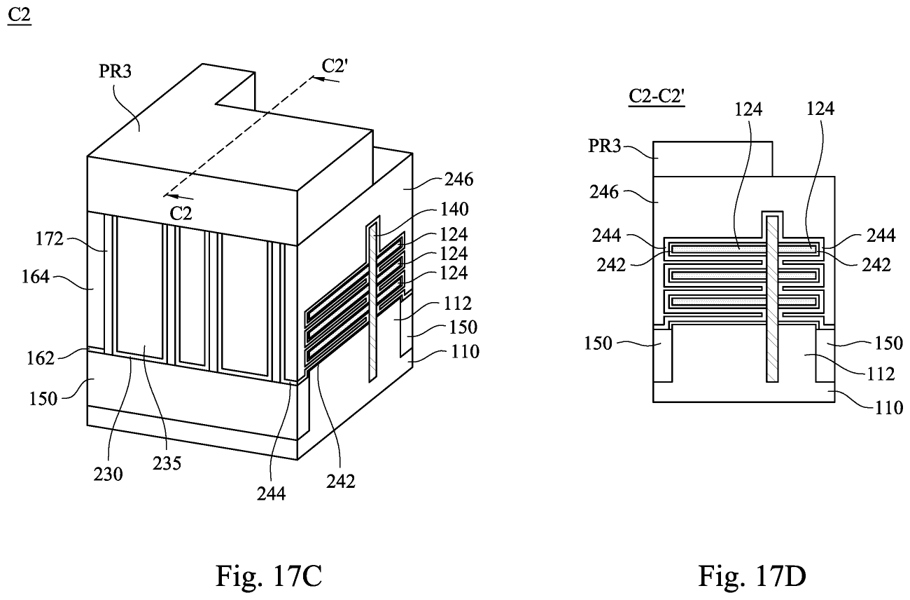

Reference is made to FIGS. 1A, 1B, and 17A-17D. A gate dielectric layer is formed in the gate trenches GT1 and the openings O1 (see FIGS. 16A-16D) and around the semiconductor layers 124. The gate dielectric layer includes an interfacial layer (e.g., silicon oxide layer) 242 and a high-k gate dielectric layer 244 over the interfacial layer 242. High-k gate dielectrics include dielectric materials having a high dielectric constant, for example, greater than that of thermal silicon oxide (˜3.9). In some embodiments, the interfacial layer 242 of the gate dielectric layer may include a dielectric material such as silicon oxide (SiO₂), HfSiO, or silicon oxynitride (SiON). The interfacial layer 242 may be formed by chemical oxidation, thermal oxidation, atomic layer deposition (ALD), chemical vapor deposition (CVD), and/or other suitable method. The high-k dielectric layer 244 of the gate dielectric layer may include hafnium oxide (HfO₂). Alternatively, the high-k dielectric layer 244 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

A second conductivity type work function metal layer 246 is formed around the high-k gate dielectric layer 244 and fills the gate trenches GT1 and the openings O1. In some embodiments, the second conductivity type work function metal layer 246 may include a single layer or multi layers. In some embodiments, the second conductivity type work function metal layer 246 can be a P-type work function metal layer or an N-type work function metal layer. In various embodiments, the second conductivity type work function metal layer 246 may include a work function that is greater than about 4.8 eV. The second conductivity type work function metal layer 246 may include Ti, TiAl, TiAlN, TaC, TaCN, TaSiN, Mn, Zr, TiN, TaN, Ru, Mo, WN, Co, Al, or any suitable materials. The second conductivity type work function metal layer 246 may be formed by ALD, PVD, CVD, or other suitable process.

After the formation of the second conductivity type work function metal layer 246, a photoresist layer PR3 is formed over the substrate 110. The photoresist layer PR3 covers portions of the second conductivity type work function metal layer 246 over the second conductivity type regions 109 but exposes other portions of the second conductivity type work function metal layer 246 over the first conductivity type regions 108. The photoresist layers PR3 further covers the dummy gate structure 160d.

Reference is made to FIGS. 1A, 1B, and 18A-18D. The portions of the second conductivity type work function metal layer 246 over the first conductivity type regions 108 are then removed by using one or more etching processes to form openings, and portions of the high-k gate dielectric layer 244 are exposed by the openings. The photoresist layer PR3 (see FIGS. 17A-17D) is then removed by using, for example, etching or ashing process.

Subsequently, a first conductivity type work function metal layer 248 is formed on the portions of the high-k gate dielectric layer 244 and fills the openings. The first conductivity type work function metal layer 248 can have an opposite conductivity to the second conductivity type work function metal layer 246. In some embodiments, first conductivity type work function metal layer 248 can be an N-type work function metal layer or a P-type work function metal layer. The first conductivity type work function metal layer 248 may include various metals that have a work function that is less than about 4.33 eV. In some embodiment, the first conductivity type work function metal layer 248 may include Ta. Alternatively, some other examples of N-metals may include (but are not limited to) Zn, Ti, Nb, Al, Ag, Mn, Zr, Hf, and La. The first conductivity type work function metal layer 248 may be formed by various deposition techniques such as physical vapor deposition (PVD or sputtering), CVD, ALD, plating, or other suitable technique. After the deposition process, a planarization process (e.g., CMP process) may be performed to remove portions of the first conductivity type work function metal layer 248 outside the openings.

In FIGS. 18A-18D, gate structures 240a are formed over the first conductivity type regions 108 (see FIGS. 1A and 1B), and gate structures 240b are formed over the second conductivity type region 109 (see FIGS. 1A and 1B). Each of the gate structures 240a includes interfacial layer 242, the high-k gate dielectric layer 244, and the first conductivity type work function metal layer 248, and each of the gate structures 240b includes interfacial layer 242, the high-k gate dielectric layer 244, and the second conductivity type work function metal layer 246. The gate structures 240a and 240b may both be referred to as gate structures 240 (see FIG. 1B). The gate structures 240a and 240b can be in parallel with each other. In some embodiments, the gate structure can be interchangeably referred to as a gate strip, a gate pattern, a gate layer, a metal gate, or a gate.

In FIGS. 18A and 18B, transistors (or nanostructure devices) Tra and Trb are formed over the first device region 102 (see FIG. 1B). The transistors Tra are N-type transistors, and the transistors Trb are P-type transistors having opposite conductivity type to the N-type transistors. In FIGS. 18C and 18D, transistors (or nanostructure devices) Trc and Trd are formed over the second device region 104 (see FIG. 1B). The transistors Trc are N-type nanosheet transistors, and the transistors Ted are P-type nanosheet transistors. As shown in FIGS. 18B and 18D, the gate structures 240a/240b of the transistors Tra, Trb, Trc, and Trd surround three sides of the semiconductor layers (channel layers) 124 and in contact with the dielectric fin 140. In some embodiments, the transistors Tra, Trb, Trc, and Trd can be interchangeably referred to fork-sheet transistors.

Fork-sheet FETs (Field-Effect Transistors) are a type of transistor technology that falls under the gate-all-around (GAA) category. In GAA transistors, the gate electrode wraps around the semiconductor channel from all sides. Fork-Sheet FETs integrate both nFET (n-type Field-Effect Transistor) and pFET (p-type Field-Effect Transistor) in the same structure, allowing for improvements in area scaling and chip density. A dielectric wall separates the nFET and pFET to ensure proper isolation between the two types of transistors. The Fork-Sheet transistors resemble a fork with branching elements or sheets. In this device architecture, the nFET and pFET channels are formed by extending and merging vertical fins that emerge from the substrate. The fins are connected by a continuous gate material that wraps around the channels, creating a gate-all-around (GAA) structure. The name “Fork-Sheet” is derived from the way these channels branch out from a common source/drain region, similar to the prongs of a fork. The extended fins, which form the nFET and pFET channels, are referred to as “sheets” due to their thin, planar structure.

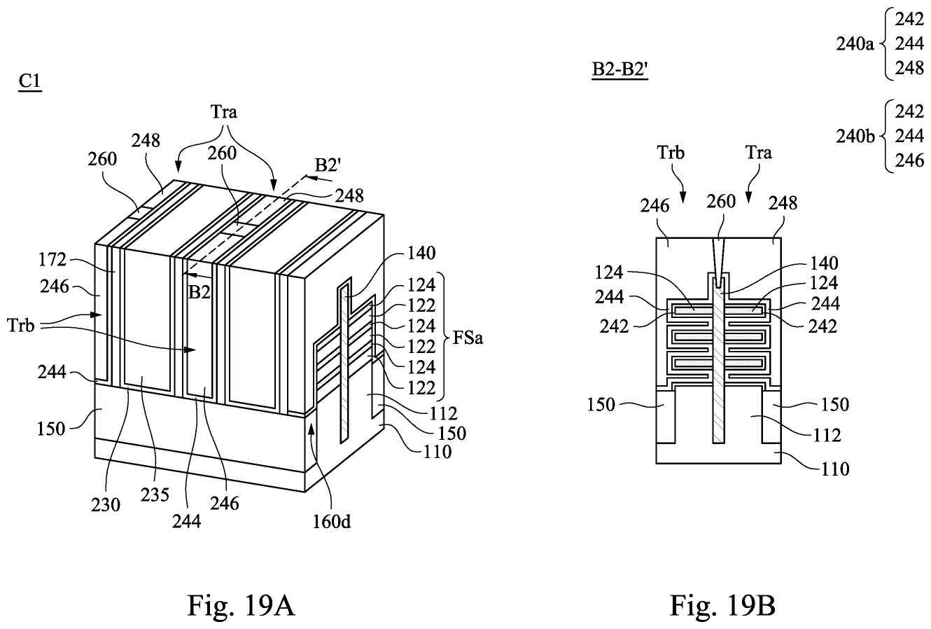

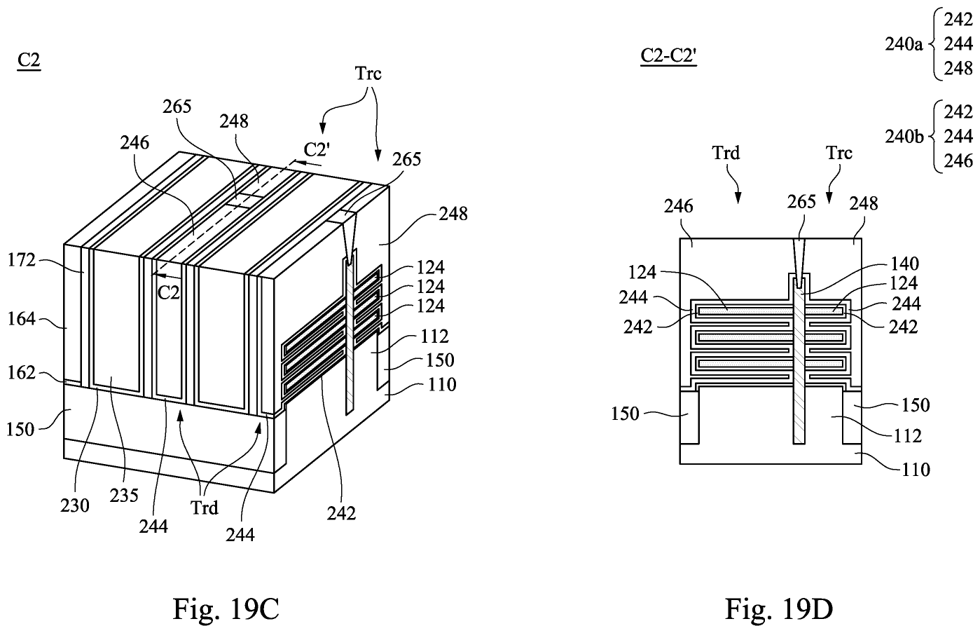

Reference is made to FIGS. 1A, 1B, and 19A-19D. As shown in FIG. 19A, first openings are formed between the gate structures 240a and 240b over the first device region 102 (see FIG. 1B). The first openings expose the dielectric fins 140 as shown in FIG. 19B. Further, as shown in FIG. 19C, second openings are formed between the gate structures 240a and 240b over the second device region 104 (see FIG. 1B). The second openings expose the dielectric fins 140 as shown in FIG. 19D. Subsequently, a dielectric material fills in the first and second openings and then a planarization process (e.g., CMP process) is performed to remove portions of the dielectric material outside the openings to form dielectric plugs 260 and 265. The dielectric plugs 260 and the dielectric film 140 together separate the gate structure 240a from the gate structure 240b over the first device region 102. On the other hand, the dielectric plugs 265 separate the gate structure 240a from the gate structure 240b over the second device region 104. In some other embodiments, the formation of one or some of the dielectric plugs 260 and 265 can be omitted when the corresponding gate structure 240a is electrically connected to the gate structure 240b. In some embodiments, the dielectric plugs 260 and 265 include low-k materials such as SiOCN, tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

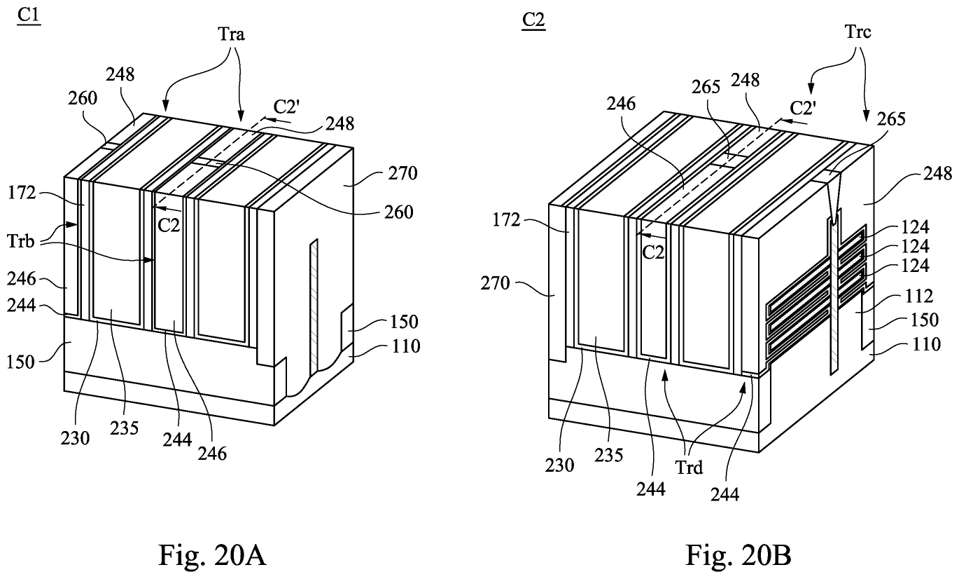

Reference is made to FIGS. 1A, 1B, 20A, and 20B. A Cut-Poly on OD Edge (CPODE) process is performed. Specifically, the dummy gate structure 160d (see FIGS. 19A and 19C) are replaced with dielectric gate structures 270, respectively. In some embodiments, the formation of dielectric gate structures 270 includes forming an etching mask covering the gate structures 240a and 240b, and using the etching mask to etch the dummy gate structure 160d. In the etching process, dummy gate structure 160d are first etched anisotropically, until the underlying fin structures FSa-FSd (see FIGS. 19A and 19C) are exposed. The fin structures FSa-FSd are then etched, and the etching continues down into the underlying protrusion structures 112. In some embodiments, the isolation structures 150 and the dielectric fins 140 are also recessed during the CPODE process. Next, a dielectric material is deposited into the resulting openings formed by the etching process, followed by a planarization process to remove excess portions of the dielectric material. The remaining dielectric material forms dielectric gate structures 270.

In accordance with some embodiments, the deposition of the dielectric material of dielectric gate structures 270 is performed using a conformal deposition process such as ALD, which may be PEALD, thermal ALD, or the like. The dielectric material may be formed of or include SiN, SiO₂, SiOC, SiOCN, or the like, or combinations thereof. The dielectric gate structures 270 may be formed of a homogenous material, or may have a composite structure including more than one layer. In some embodiments, the dielectric material of dielectric gate structures 270 includes SiN.

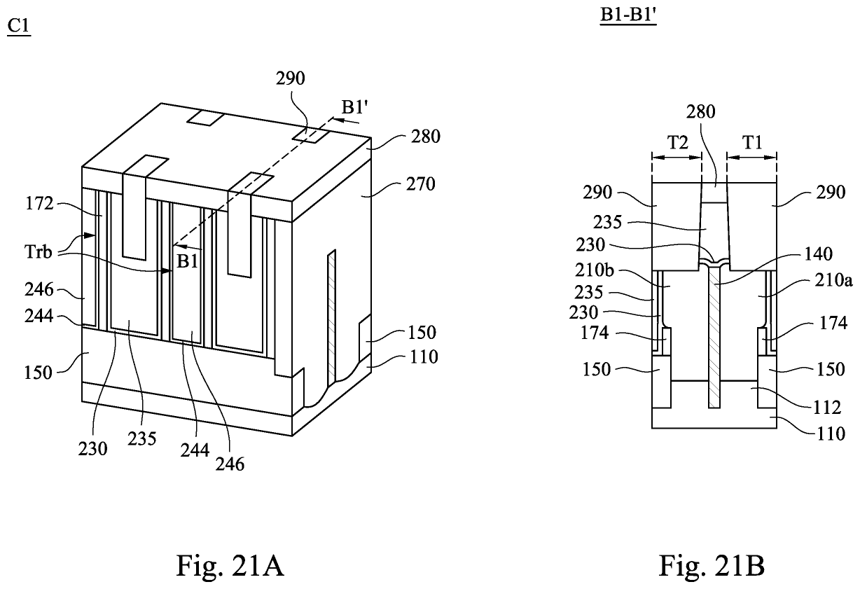

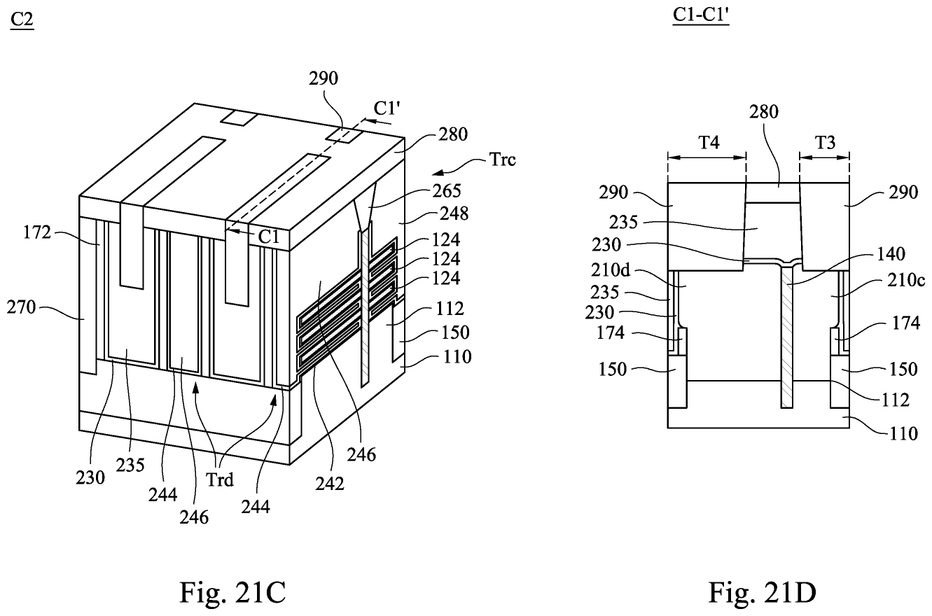

Reference is made to FIGS. 1A, 1B, and 21A-21D. Another ILD layer 280 is formed over the structure illustrated in FIGS. 20A and 20B. In some embodiments, the ILD layer 280 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and the like. In certain embodiments, the ILD layer 280 is formed of silicon oxide (SiOₓ). The ILD layer 280 may be deposited by a PECVD process or other suitable deposition technique.

The ILD layers 235 and 280 are then patterned to form contact trenches on the source/drain epitaxial structures 210a-210d, and then the CESL 230 is patterned to expose the source/drain epitaxial structures 210a-210d. In some embodiments, multiple etching processes are performed to pattern the ILD layers 235 and 280 and the CESL 230. The etching processes include dry etching process, wet etching process, or combinations thereof.

Source/drain contacts 290 are then formed in the contact trenches. As such, the source/drain contacts 290 are electrically connected to the source/drain epitaxial structures 210a-210d. In some embodiments, the source/drain contacts 290 may be made of metal, such as W, Co, Ru, Mo, Al, Cu, or other suitable materials. After the deposition of the source/drain contacts 290, a planarization process, such as a chemical mechanical planarization (CMP) process, may be then performed. In some embodiments, barrier layers may be formed in the contact trenches before the formation of the source/drain contacts 290. The barrier layers may be made of Ti, TiN, Ta, TaN, Ru, Co, or combinations thereof.

As shown in FIGS. 21A-21D, for a source/drain contact 290 (which is connected to the source/drain epitaxial structure 210a, 210b, 210c, or 210d), the length of the source/drain contact 290 over the source/drain epitaxial structure 210d can be greater than the length of the source/drain contacts 290 over the source/drain epitaxial structure 210a, 210b, and 210c by about 1.1 times to about 10 times due to the large channel pitch in the Y-direction. Therefore, source/drain vias formed over the source/drain contacts have different sizes over the source/drain epitaxial structure 210a, 210b, 210c, and 210d. For example, the source/drain vias formed over the source/drain epitaxial structure 210d have sizes is about 1.1 times to about 10 times the sizes of the source/drain vias formed over the source/drain epitaxial structure 210a, 210b, and 210c. In FIGS. 21B and 21D, the source/drain contact 290 over the source/drain epitaxial structure 210a has a width T1, the source/drain contact 290 over the source/drain epitaxial structure 210b has a width T2, the source/drain contact 290 over the source/drain epitaxial structure 210c has a width T3, and the source/drain contact 290 over the source/drain epitaxial structure 210d has a width T4 greater than the widths T1-T3, and thus and thus transistor Trd (see FIGS. 18A and 18B) in the unit cell 101a (see FIG. 1A) can have a greater source/drain contact width than other transistors. The widths T1, T2, T3, and T4 are dimensions extending in the direction perpendicular to the lengthwise direction of the dielectric fin 140 as shown in FIG. 1B. By way of example and not limitation, the width T4 may be greater than any one of the widths T1-T3 about 1.1 times, such as about 1.1, 1.5, 2, 2.5, 3, 3.5, 4, 4.5, 5, 5.5, 6, 6.5, 7, 7.5, 8, 8.5, 9, 7.5, or 10 times. A greater source/drain contact width can reduce contact resistance between the source/drain region and the external circuitry, leading to improved device performance and reduced power dissipation. This is beneficial for high-performance and power-sensitive applications. In addition, the ability to vary the source/drain contact width of the nFET or pFET in the Forksheet FET within the enlarged unit cell enables to optimize transistor characteristics based on the requirements of the application. This provides greater flexibility in adjusting performance and power trade-offs in the semiconductor device.

The structure in FIGS. 21A-21D may further undergo the manufacturing processes such as the formation of gate vias, which may be formed in the ILD layer 280 and connected to the gate structures 240a and/or 240b. In some embodiments, there is no gate via formed over the dielectric gate structures 270, such that the ILD layer 280 may completely covers the dielectric gate structures 270.

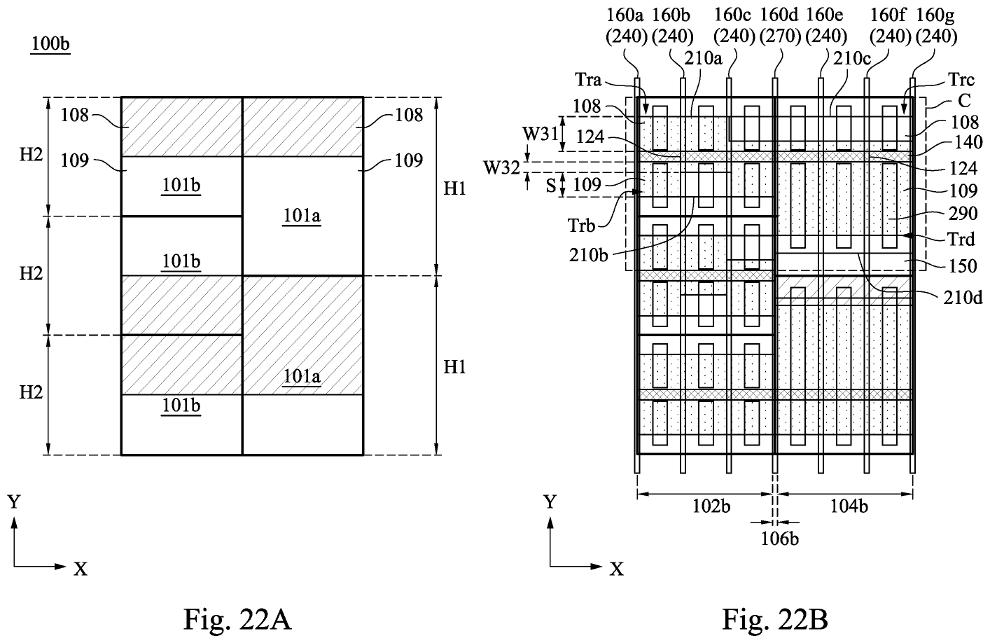

Reference is made to FIGS. 22A and 22B. FIG. 22A is a top view of a cell array of an integrated circuit structure 100b (or semiconductor device) in accordance with some embodiments of the present disclosure. FIG. 22B is a layout diagram of an integrated circuit structure 100b (or semiconductor device) in accordance with some embodiments of the present disclosure. While FIGS. 22A and 22B show an embodiment of the integrated circuit structure 100b with different channel region top view profiles than the integrated circuit structure 100a in FIGS. 1A-21D. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 22A and 22B, the difference between the embodiment in FIGS. 22A and 22B and the embodiment in FIGS. 1A-21D is in that the fork-sheet transistors in different device regions (or different columns of the cell array) each can have a channel region width difference between the channel regions on opposite sides of the dielectric fin 140. In some embodiments, the unit cell on the device region 102b (or left column) of the cell array as shown in FIG. 22B can have different channel region widths W31 and W32, where the channel region width W32 is wider than the channel region width W31 and is limited by the minimum space of the isolation structure 150 (see FIGS. 21A-21D), and the difference between channel region widths W31 and W32 can be denote as a difference s. This disclosure can provide a broader range of device options on the unit cells on the device region 104b (or right column of the cell array) as shown in FIG. 22B. That is, the channel region width W34 on the device region 104b of the cell array as shown in FIG. 22B can be greater than 1.5 times the channel region width W32, and the minimum width of the channel region width W33 in the device region 104b of the cell array can be the same as the minimum width of the channel region width W31 in the device region 102b of the cell array.

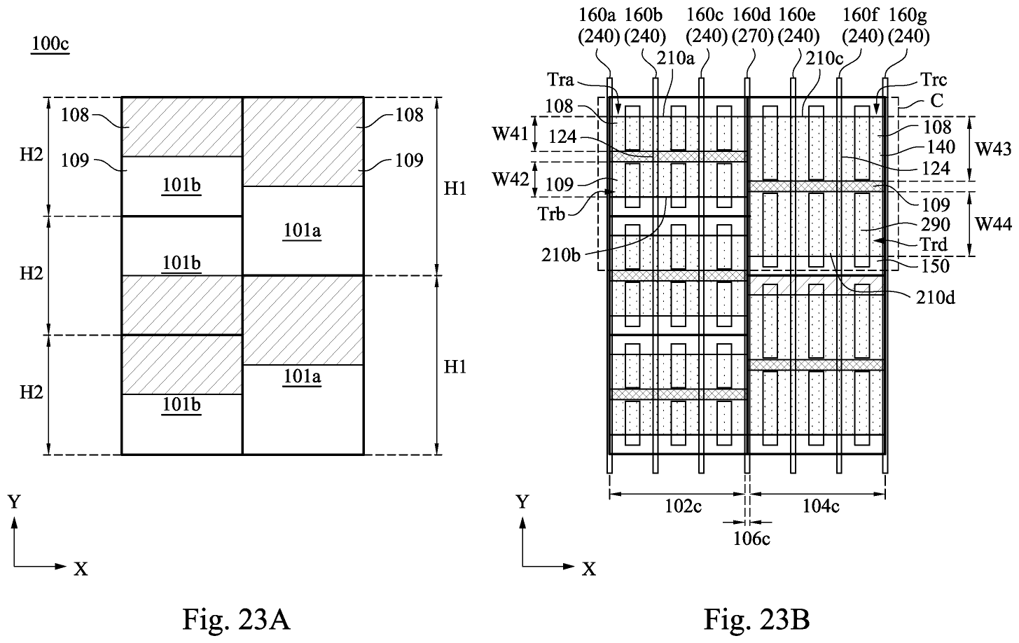

Reference is made to FIGS. 23A and 23B. FIG. 23A is a top view of a cell array of an integrated circuit structure 100c (or semiconductor device) in accordance with some embodiments of the present disclosure. FIG. 23B is a layout diagram of an integrated circuit structure 100c (or semiconductor device) in accordance with some embodiments of the present disclosure. While FIGS. 23A and 23B show an embodiment of the integrated circuit structure 100c with a different dielectric fin arrangement than the integrated circuit structure 100a in FIGS. 1A-21D. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 23A and 23B, the difference between the embodiment in FIGS. 22A and 22B and the embodiment in FIGS. 1A-21D is in that, in the cell array, the dielectric fins 140 within the two unit cells adjacent to the device regions 102c and 104c (or left and right columns of the cell array) can be misaligned, resulting in an offset. Specifically, the isolation wall 140 in the second device region 104 is offset from the other isolation wall 140 in the first device region 102 along the direction perpendicular to the lengthwise direction of the isolation wall 140 in the first device region 102 by a non-zero distance. As a consequence, the unit cell situated in the device region 104c (or right column of the cell array) can be partitioned into similar spaces by the dielectric fin 140, allowing components on both sides of the dielectric fin 140 to have comparable dimensions, such as analogous channel region widths W43 and W44. In some embodiment, both of the channel region widths W43 and W44 in the same unit cell on the device region 104c (or right column of the cell array) are greater than the channel region widths W41 and W42 on the device region 102c (or left column of the cell array).

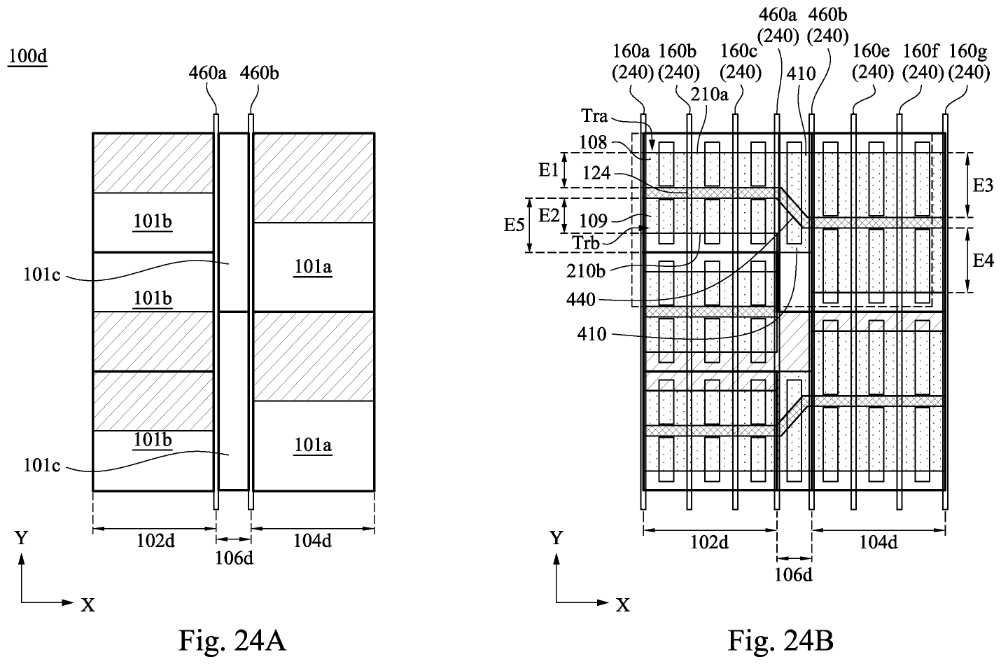

Reference is made to FIGS. 24A and 24B. FIG. 24A is a top view of a cell array of an integrated circuit structure 100d (or semiconductor device) in accordance with some embodiments of the present disclosure. FIG. 24B is a layout diagram of an integrated circuit structure 100d (or semiconductor device) in accordance with some embodiments of the present disclosure. While FIGS. 24A and 24B show an embodiment of the integrated circuit structure 100d with additional non-functional gates than the integrated circuit structure 100c in FIGS. 23A and 23B. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 24A and 24B, the cell array in this embodiment incorporates transition cells 101c that form a shared border region 106d (or an intermediate column of the cell array) between the device regions 102d and 104d (or left and right columns of the cell array) as shown in FIGS. 1A, 22A, and 23A. These cells 101c serve as a bridge between the device regions 102d and 104d, ensuring a seamless connection and improving overall device performance. At the boundaries of the transition cells 101c, two non-functional gates 460a and 460b are integrated. These non-functional gates 460a and 460b do not contribute to the active operation of the device but play a role in stabilizing the cell array and maintaining the desired electrical properties. The non-functional gates 460a and 460b can lead to improved device stability, better control over electrical properties, and increased design flexibility, allowing for more sophisticated and complex circuits. This embodiment stands apart from previous embodiments due to the incorporation of additional non-functional gates in the integrated circuit structure 100d. This design choice enhances the overall performance and stability of the semiconductor device. As shown in FIG. 24B, an intermediate dielectric fin 440 is formed to extend from the non-functional gate 460a to the non-functional gate 460b. The direction in which the dielectric fin 440 extends is at a non-90-degree angle to the non-functional gates 460a and 460b. Non-functional source/drain epitaxial structures 410 formed in the cells have widths E5 in parallel with the lengthwise direction of the non-functional gate 460a from the top view. In some embodiments, the widths E5 may be greater than the widths E1 and E2 of the source/drain epitaxial structures in the device region 102d (or left column of the cell array) and less than the widths E3 and E4 of the source/drain epitaxial structures in the device region 104d (or right column of the cell array). In some embodiments, the intermediate dielectric fin 440 can be interchangeably referred to an isolation wall, an isolation strip, an isolation line, or an isolation pattern.

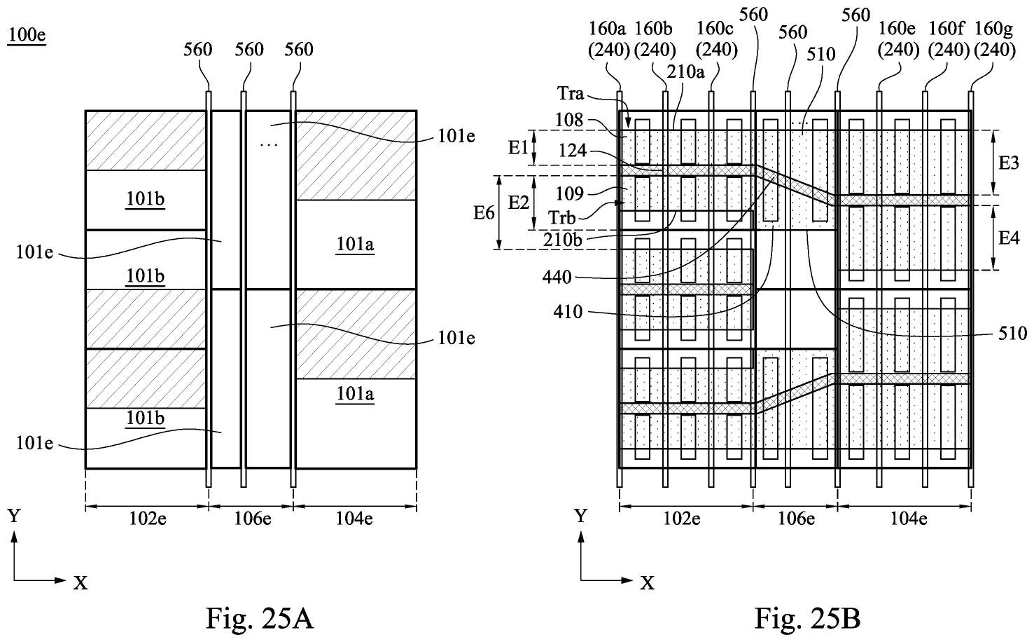

Reference is made to FIGS. 25A and 25B. FIG. 25A is a top view of a cell array of an integrated circuit structure 100e (or semiconductor device) in accordance with some embodiments of the present disclosure. FIG. 25B is a layout diagram of an integrated circuit structure 100e (or semiconductor device) in accordance with some embodiments of the present disclosure. While FIGS. 25A and 25B show an embodiment of the integrated circuit structure 100e with more additional non-functional gates than the integrated circuit structure 100c in FIGS. 24A and 24B. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 25A and 25B, the cell array in this embodiment incorporates transition cells 101e that form a shared border region 106e (or an intermediate column of the cell array) between the device regions 102e and 104e (or left and right columns of the cell array) as shown in FIGS. 1A, 22A, and 23A. These cells 101e serve as a bridge between the device regions 102e and 104c, ensuring a seamless connection and improving overall device performance. At the boundaries of the transition cells 101c, two of the non-functional gates 560 are integrated. These non-functional gates 560 do not contribute to the active operation of the device but play a role in stabilizing the cell array and maintaining the desired electrical properties. The non-functional gates 560 can lead to improved device stability, better control over electrical properties, and increased design flexibility, allowing for more sophisticated and complex circuits. This embodiment stands apart from previous embodiments due to the incorporation of more than two non-functional gates in the integrated circuit structure 100c. This design choice enhances the overall performance and stability of the semiconductor device. As shown in FIG. 25B, an intermediate dielectric fin 540 is formed to extend from one of the non-functional gate 560 at the boundary of the transition cells 101e to another one of the non-functional gate 560 at the boundary of the transition cells 101c. The direction in which the dielectric fin 540 extends is at a non-90-degree angle to the non-functional gates 560. Non-functional source/drain epitaxial structures 510 formed in the cells have widths E6 in parallel with the lengthwise direction of the non-functional gate 560 from the top view. In some embodiments, the widths E6 may be greater than the widths E1 and E2 of the source/drain epitaxial structures in the device region 102c (or left column of the cell array) and less than the widths E3 and E4 of the source/drain epitaxial structures in the device region 104e (or right column of the cell array).

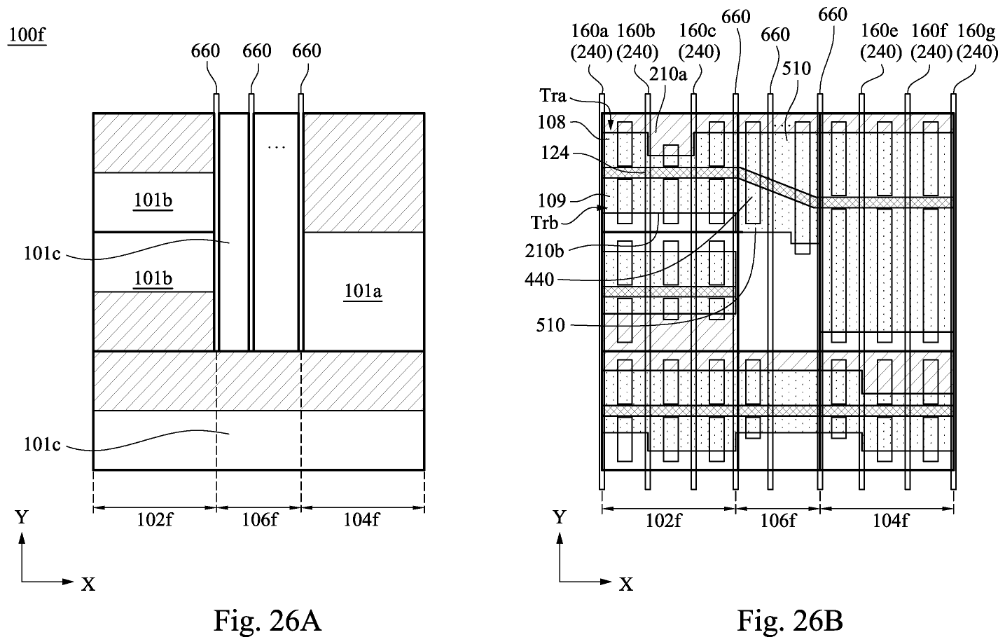

Reference is made to FIGS. 26A and 26B. FIG. 26A is a top view of a cell array of an integrated circuit structure 100f (or semiconductor device) in accordance with some embodiments of the present disclosure. FIG. 26B is a layout diagram of an integrated circuit structure 100f (or semiconductor device) in accordance with some embodiments of the present disclosure. While FIGS. 26A and 26B show an embodiment of the integrated circuit structure 100f with different cell arrangement than the integrated circuit structure 100a in FIGS. 1A-25B. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 26A and 26B, the disclosure merges N-type transistors (or P-type transistors) in the device region 104f (or right column of the cell array) on a height exceeding 1.5 times (e.g. about twice) the height of the device in the device region 102f (or left column of the cell array). This merging process provides a wider device width option, enabling enhanced performance for applications that require higher speeds. Despite the merging of FS devices, other cells in the device region 104f (or right column of the cell array) can maintain the same height as the cells in the device region 102f (or left column of the cell array). This feature ensures a consistent and streamlined cell array structure while still offering the flexibility to accommodate various performance requirements. In addition, the non-functional gate 660 in in FIGS. 26A and 26B does not fully extend across the device regions (or columns in the cell array). This design choice allows active regions containing transistors to extend laterally across the non-functional gates, optimizing device performance and area scaling. The introduction of merged transistors on a greater height and the modified non-functional gate design can enhance device performance for high-speed applications, increased design flexibility, improved area scaling, and better device reliability.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method for partially removing the “isolation-wall” structure in standard cells (STD) to create a wider Fork-Sheet (FS) device across multiple heights of the original STD unit. Moreover, the width of the wider FS device can be adjusted by altering the position of the “isolation-wall” within the cell. Consequently, this disclosure presents a method to merge N-type (or P-type) FS device regions within a standard cell to form an expanded device region. It replaces the isolation wall with a minimum isolation space between the adjacent two wider FS devices, allowing the wider FS device to increase to more than 1.5 times the original wider FS device.

In some embodiments, a method includes forming first, second, third, fourth, fifth, and sixth channel patterns on a semiconductor substrate; forming a first isolation wall interposing the first and second channel patterns and in contact with the first and second channel patterns, a second isolation wall interposing the third and fourth channel patterns and in contact with the third and fourth channel patterns, wherein the first isolation wall further continuously extends to interpose the fifth and sixth channel patterns; forming a first gate pattern extending across the first, second, third, and fourth channel patterns and the first and second isolation walls, and a second gate pattern extending across the fifth and sixth channel patterns and the first isolation wall from a top view, wherein the first, second, third, fourth, and fifth channel patterns respectively have first, second, third, fourth, and fifth dimensions in a lengthwise direction of the first gate pattern, and the fifth dimension is greater than the first, second, third, and fourth dimensions; forming first source/drain patterns on the first channel pattern, second source/drain patterns on the second channel pattern, third source/drain patterns on the third channel pattern, fourth source/drain patterns on the fourth channel pattern, fifth source/drain patterns on the fifth channel pattern, and sixth source/drain patterns on the sixth channel pattern channel pattern. In some embodiments, second gate pattern non-overlaps the second isolation wall. In some embodiments, the fifth dimension of the fifth channel pattern is greater than 1.5 times of one of the first, second, third, and fourth dimensions of the first, second, third, and fourth dimensions channel patterns. In some embodiments, the fifth dimension of the fifth channel pattern is greater than a sixth dimension of the sixth channel pattern in the lengthwise direction of the first gate pattern. In some embodiments, the fifth dimension of the fifth channel pattern is the same as a sixth dimension of the sixth channel pattern in the lengthwise direction of the first gate pattern. In some embodiments, the first dimension of the first channel pattern is different than the second dimension of the second channel pattern. In some embodiments, the first dimension of the first channel pattern is the same as the second dimension of the second channel pattern. In some embodiments, the method further incudes forming a third gate pattern extending in parallel with the first and second gate patterns and between the first and second gate patterns, the third gate pattern extending across the first isolation wall and non-overlapping the second isolation wall. In some embodiments, the method further incudes forming a fourth gate pattern extending in parallel with the first and second gate patterns and between the first and second gate patterns, the fourth gate pattern extending across the first isolation wall and non-overlapping the second isolation wall. In some embodiments, the first channel pattern is of a first n-type transistor, the second channel pattern is of a first p-type transistor, the third channel pattern is of a second p-type transistor, the fourth channel pattern is of a second n-type transistor, the fifth channel pattern is of a third n-type transistor, and the sixth channel pattern is of a third p-type transistor.

In some embodiments, a method includes forming a first unit cell over a semiconductor substrate, the first unit cell comprising a plurality of first nanostructures of a first transistor and a plurality of second nanostructures of a second transistor, the second transistor being of a conductivity type opposite to a conductivity type of the first transistor; forming a second unit cell over the semiconductor substrate, the second unit cell comprising a plurality of third nanostructures of a third transistor and a plurality of fourth nanostructures of a fourth transistor, the fourth transistor being of a conductivity type opposite to a conductivity type of the third transistor; forming a first isolation wall interposing the first nanostructures and the second nanostructures, wherein from a first cross-sectional view, the first nanostructures laterally extend from a first sidewall of the first isolation wall, and the second nanostructures laterally extend from a second sidewall of the first isolation wall opposing the first sidewall; forming a second isolation wall extending in parallel with the first isolation wall from a top view, the second isolation wall interposing the third nanostructures and the fourth nanostructures, wherein from a second cross-sectional view, the third nanostructures laterally extend from a third sidewall of the second isolation wall, and the fourth nanostructures laterally extend from a fourth sidewall of the second isolation wall opposing the third sidewall, and from the top view, the second unit cell has a height greater than about 1.5 times of a height of the first unit cell in a direction perpendicular to a lengthwise direction of the first isolation wall. In some embodiments, the height of the second unit cell is about twice of the height of the first unit cell. In some embodiments, a longitudinal end of the first isolation wall is in contact with a longitudinal end of the second isolation wall. In some embodiments, the second isolation wall is offset from the first isolation wall along the direction perpendicular to the lengthwise direction of the first isolation wall by an non-zero distance. In some embodiments, the method further incudes forming a third isolation wall extending from a longitudinal end of the first isolation wall to a longitudinal end of the second isolation wall.

In some embodiments, the semiconductor structure includes an first isolation strip, first, second, third, and fourth semiconductor sheets, first, second, third, and fourth gate structures, and first, second, third, and fourth source/drain structures. The first isolation strip laterally extends above a semiconductor substrate. The semiconductor substrate has first and second unit cells. The first semiconductor sheets laterally extend from a first sidewall of the first isolation strip and are arranged in a vertical direction within the first unit cell from a first cross-sectional view. The second semiconductor sheets laterally extend from a second sidewall of the first isolation strip opposing the first sidewall, and the plurality of the second semiconductor sheets are arranged in the vertical direction within the first unit cell from the first cross-sectional view. The third semiconductor sheets laterally extend from the first sidewall of the first isolation strip and are arranged in the vertical direction within the second unit cell from a second cross-sectional view. The fourth semiconductor sheets laterally extend from the second sidewall of the first isolation strip and are arranged in the vertical direction within the second unit cell from the second cross-sectional view. The third semiconductor sheets have greater dimensions than the first and second semiconductor sheets in a direction perpendicular to the first isolation strip from a top view. The first, second, third, and fourth gate structures surround the first, second, third, and fourth semiconductor sheets. The first, second, third, and fourth source/drain structures are on the first, second, third, and fourth semiconductor sheets. In some embodiments, the third source/drain structures have greater dimensions than the first source/drain structures in the direction perpendicular to the first isolation strip from the top view. In some embodiments, the semiconductor structure further includes a first source/drain contact and a second source/drain contact. The first source/drain contact is over the first source/drain structure. The second source/drain contact is over the fourth source/drain structure. The second source/drain contact has a greater dimension than the first source/drain contact in the direction perpendicular to a lengthwise direction of the first isolation strip from the top view. In some embodiments, the dimensions of the third semiconductor sheets are different than the fourth semiconductor sheets in the direction perpendicular to the first isolation strip from the top view. In some embodiments, the semiconductor structure further includes a second isolation strip laterally extending above a third unit cell within the semiconductor substrate. The second isolation strip laterally extends in parallel with the first second isolation strip. The second isolation strip has a shorter length than the first isolation strip from the top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming first, second, third, fourth, fifth, and sixth channel patterns on a semiconductor substrate;
forming a first isolation wall interposing the first and second channel patterns and in contact with the first and second channel patterns, a second isolation wall interposing the third and fourth channel patterns and in contact with the third and fourth channel patterns, wherein the first isolation wall further continuously extends to interpose the fifth and sixth channel patterns;
forming a first gate pattern extending across the first, second, third, and fourth channel patterns and the first and second isolation walls, and a second gate pattern extending across the fifth and sixth channel patterns and the first isolation wall from a top view, wherein the first, second, third, fourth, and fifth channel patterns respectively have first, second, third, fourth, and fifth dimensions in a lengthwise direction of the first gate pattern, and the fifth dimension is greater than the first, second, third, and fourth dimensions; and
forming first source/drain patterns on the first channel pattern, second source/drain patterns on the second channel pattern, third source/drain patterns on the third channel pattern, fourth source/drain patterns on the fourth channel pattern, fifth source/drain patterns on the fifth channel pattern, and sixth source/drain patterns on the sixth channel pattern.

2. The method of claim 1, wherein the second gate pattern non-overlaps the second isolation wall.

3. The method of claim 1, wherein the fifth dimension of the fifth channel pattern is greater than 1.5 times of one of the first, second, third, and fourth dimensions of the first, second, third, and fourth dimensions channel patterns.

4. The method of claim 1, wherein the fifth dimension of the fifth channel pattern is greater than a sixth dimension of the sixth channel pattern in the lengthwise direction of the first gate pattern.

5. The method of claim 1, wherein the fifth dimension of the fifth channel pattern is the same as a sixth dimension of the sixth channel pattern in the lengthwise direction of the first gate pattern.

6. The method of claim 1, wherein the first dimension of the first channel pattern is different than the second dimension of the second channel pattern.

7. The method of claim 1, wherein the first dimension of the first channel pattern is the same as the second dimension of the second channel pattern.

8. The method of claim 1, further comprising:
forming a third gate pattern extending in parallel with the first and second gate patterns and between the first and second gate patterns, the third gate pattern extending across the first isolation wall and non-overlapping the second isolation wall.

9. The method of claim 8, further comprising:
forming a fourth gate pattern extending in parallel with the first and second gate patterns and between the first and second gate patterns, the fourth gate pattern extending across the first isolation wall and non-overlapping the second isolation wall.

10. The method of claim 1, wherein the first channel pattern is of a first n-type transistor, the second channel pattern is of a first p-type transistor, the third channel pattern is of a second p-type transistor, the fourth channel pattern is of a second n-type transistor, the fifth channel pattern is of a third n-type transistor, and the sixth channel pattern is of a third p-type transistor.

11. A method, comprising:
forming a first unit cell over a semiconductor substrate, the first unit cell comprising a plurality of first nanostructures of a first transistor and a plurality of second nanostructures of a second transistor, the second transistor being of a conductivity type opposite to a conductivity type of the first transistor;
forming a second unit cell over the semiconductor substrate, the second unit cell comprising a plurality of third nanostructures of a third transistor and a plurality of fourth nanostructures of a fourth transistor, the fourth transistor being of a conductivity type opposite to a conductivity type of the third transistor;
forming a first isolation wall interposing the first nanostructures and the second nanostructures, wherein from a first cross-sectional view, the first nanostructures laterally extend from a first sidewall of the first isolation wall, and the second nanostructures laterally extend from a second sidewall of the first isolation wall opposing the first sidewall; and
forming a second isolation wall extending in parallel with the first isolation wall from a top view, the second isolation wall interposing the third nanostructures and the fourth nanostructures, wherein from a second cross-sectional view, the third nanostructures laterally extend from a third sidewall of the second isolation wall, and the fourth nanostructures laterally extend from a fourth sidewall of the second isolation wall opposing the third sidewall, and from the top view, the second unit cell has a height greater than about 1.5 times of a height of the first unit cell in a direction perpendicular to a lengthwise direction of the first isolation wall.

12. The method of claim 11, wherein a longitudinal end of the first isolation wall is in contact with a longitudinal end of the second isolation wall.

13. The method of claim 11, wherein the second isolation wall is offset from the first isolation wall along the direction perpendicular to the lengthwise direction of the first isolation wall by an non-zero distance.

14. The method of claim 13, further comprising:
forming a third isolation wall extending from a longitudinal end of the first isolation wall to a longitudinal end of the second isolation wall.

15. The method of claim 11, wherein the height of the second unit cell is about twice of the height of the first unit cell.

16. A semiconductor structure, comprising:
an first isolation strip laterally extending above a semiconductor substrate, the semiconductor substrate having first and second unit cells;
a plurality of first semiconductor sheets laterally extending from a first sidewall of the first isolation strip and arranged in a vertical direction within the first unit cell from a first cross-sectional view;
a plurality of second semiconductor sheets laterally extending from a second sidewall of the first isolation strip opposing the first sidewall, and the plurality of second semiconductor sheets arranged in the vertical direction within the first unit cell from the first cross-sectional view;
a plurality of third semiconductor sheets laterally extending from the first sidewall of the first isolation strip and arranged in the vertical direction within the second unit cell from a second cross-sectional view;
a plurality of fourth semiconductor sheets laterally extending from the second sidewall of the first isolation strip and arranged in the vertical direction within the second unit cell from the second cross-sectional view, wherein the third semiconductor sheets have greater dimensions than the first and second semiconductor sheets in a direction perpendicular to the first isolation strip from a top view;
first, second, third, and fourth gate structures surrounding the first, second, third, and fourth semiconductor sheets; and
first, second, third, and fourth source/drain structures on the first, second, third, and fourth semiconductor sheets.

17. The semiconductor structure of claim 16, wherein the third source/drain structures have greater dimensions than the first source/drain structures in the direction perpendicular to the first isolation strip from the top view.

18. The semiconductor structure of claim 16, further comprising:
a first source/drain contact over the first source/drain structure; and
a second source/drain contact over the fourth source/drain structure,
wherein the second source/drain contact has a greater dimension than the first source/drain contact in the direction perpendicular to a lengthwise direction of the first isolation strip from the top view.

19. The semiconductor structure of claim 16, wherein the dimensions of the third semiconductor sheets are different than the fourth semiconductor sheets in the direction perpendicular to the first isolation strip from the top view.

20. The semiconductor structure of claim 16, further comprising:
a second isolation strip laterally extending above a third unit cell within the semiconductor substrate, the second isolation strip laterally extending in parallel with the first isolation strip, and the second isolation strip having a shorter length than the first isolation strip from the top view.
